(19) United States
(12) Patent Application Publication
(10) Pub. No.: US 2026/0271491 A1
(43) Pub. Date: Sep. 10, 2026

(54) LIGHT-EMITTING ELEMENT, DISPLAY DEVICE, AND METHOD FOR MANUFACTURING LIGHT-EMITTING ELEMENT

(71) Applicant: Sharp Display Technology Corporation, Kameyama City, Mie (JP)

(72) Inventor: Yuma YAGUCHI, Sakai City, Osaka (JP)

(21) Appl. No.: 19/118,842

(22) PCT Filed: Oct. 14, 2022
(86) PCT No.: PCT/JP2022/038463

§ 371 Date: Apr. 7, 2025

(51) Int. Cl. H10K 50/115

(52) U.S. Cl. CPC H10K 50/115

(57) ABSTRACT

A light-emitting element includes an anode electrode and a cathode electrode and an EML including QDs and an MX. The MX has a first region containing an inorganic compound and a second region containing an inorganic compound in a direction of a straight line passing through an outer edge part on an anode electrode side and an outer edge part on a cathode electrode side in the EML, and a concentration of the inorganic compound in the first region is different from a concentration of the inorganic compound in the second region by at least a certain amount.

### TECHNICAL FIELD

The disclosure relates to a light-emitting element, a display device, and a method for manufacturing a light-emitting element.

### BACKGROUND ART

PTL 1 discloses a quantum dot device including a quantum dot layer containing luminescent quantum dots and non-luminescent quantum dots in order to improve luminescence characteristics, and discloses that the luminescent quantum dots exhibit a quantum confinement effect by having a shell with a larger band gap than a core, thereby emitting light.

### CITATION LIST

### Patent Literature

PTL 1: US 2019/280,232 A

### SUMMARY

### Technical Problem

However, in PTL 1, organic ligands such as oleic acids are coordinated to these quantum dots. Organic ligands composed of organic substances have problems in that the organic ligands have low stability and are easily peeled off, leading to a decrease in luminescence characteristics and a decrease in reliability.

Therefore, covering the quantum dots with an inorganic medium instead of the organic ligands provides strong protection for the quantum dots. However, when the quantum dots are uniformly covered with the inorganic medium, use of an inorganic compound having a large band gap as the inorganic medium in order to exert the quantum confinement effect causes a decrease in efficiency of carrier injection of holes and electrons into the quantum dots, resulting in a decrease in luminous efficiency.

One aspect of the disclosure has been made in view of the above problems, and an object of the disclosure is to provide a light-emitting element and a display device that have high stability, high luminous efficiency, and high reliability, and a method for manufacturing a light-emitting element.

### Solution to Problem

In order to solve the problems described above, a light-emitting element according to an aspect of the disclosure includes a first electrode, a second electrode, and a light-emitting layer located between the first electrode and the second electrode, in which the light-emitting layer includes multiple quantum dots and a matrix material, the matrix material includes a first inorganic compound and a second inorganic compound, the matrix material includes, in a direction of a straight line passing through a first outer edge part on a first electrode side and a second outer edge part on a second electrode side in the light-emitting layer, a first region including at least the first inorganic compound and a second region including at least the second inorganic compound, the second region is located closer to the second outer edge part than the first region, and a concentration of the first inorganic compound in the first region and a concentration of the first inorganic compound in the second region are different by at least a certain amount.

In order to solve the problems described above, a display device according to an aspect of the disclosure includes the above-described light-emitting element according to an aspect of the disclosure.

In order to solve the problems described above, a method for manufacturing a light-emitting element according to an aspect of the disclosure is a method for manufacturing a light-emitting element including a first electrode, a second electrode, and a light-emitting layer located between the first electrode and the second electrode, the light-emitting layer including multiple quantum dots and a matrix material, the matrix material including a first inorganic compound and a second inorganic compound, the matrix material including, in a direction of a straight line passing through a first outer edge part on a first electrode side and a second outer edge part on a second electrode side in the light-emitting layer, a first region including at least the first inorganic compound and a second region including at least the second inorganic compound, the second region being located closer to the second outer edge part than the first region, and a concentration of the first inorganic compound in the first region being different from a concentration of the first inorganic compound in the second region by at least a certain amount, and the method includes forming the light-emitting layer. The forming the light-emitting layer includes (1) by applying a quantum dot dispersion including the multiple quantum dots, a precursor of the first inorganic compound, halide ions, and a first solvent, and forming the first inorganic compound by thermally decomposing the precursor of the first inorganic compound, forming a coating film consisting of the quantum dot dispersion, (2) by heating the coating film consisting of the quantum dot dispersion at a temperature equal to or higher than a thermal decomposition temperature of the precursor of the first inorganic compound and thermally decomposing at least part of the precursor of the first inorganic compound, and removing the first solvent, forming a first film including the multiple quantum dots and a matrix material including the first inorganic compound, (3) supplying, onto the first film, a second inorganic compound precursor solution including a precursor of the second inorganic compound and a second solvent, and forming the second inorganic compound by thermally decomposing the precursor of the second inorganic compound, and (4) by heating the second inorganic compound precursor solution supplied in the supplying a second inorganic compound precursor solution at a temperature equal to or higher than a thermal decomposition temperature of the precursor of the second inorganic compound, and thermally decomposing at least part of the precursor of the second inorganic compound and removing the second solvent, forming a matrix material including the second inorganic compound.

### Advantageous Effects of Disclosure

According to one aspect of the disclosure, it is possible to provide a light-emitting element and a display device that have high stability, high luminous efficiency, and high reliability, and a method for manufacturing a light-emitting element.

### BRIEF DESCRIPTION OF DRAWINGS

FIG. 1 is a cross-sectional view illustrating an example of a schematic configuration of a light-emitting element according to a first embodiment.

FIG. 2 is a cross-sectional view illustrating an example of a schematic configuration of a quantum dot and its vicinity in the light-emitting element illustrated in FIG. 1.

FIG. 3 is a cross-sectional view illustrating a state in which quantum dots adjacent to each other are close to each other in the light-emitting element illustrated in FIG. 1.

FIG. 4 is a cross-sectional view schematically illustrating a state of carrier injection in a comparative light-emitting element in which quantum dots are uniformly covered with a matrix material composed of an inorganic compound.

FIG. 5 is a diagram illustrating energy band structures of function layers according to the comparative light-emitting element illustrated in FIG. 4.

FIG. 6 is a cross-sectional view schematically illustrating a state of carrier injection in the light-emitting element according to the first embodiment when a first inorganic compound is indium sulfide and a second inorganic compound is magnesium sulfide.

FIG. 7 is a diagram illustrating energy band structures of function layers in the light-emitting element illustrated in FIG. 6.

FIG. 8 is a cross-sectional view illustrating an example of a direction of measurement of concentrations of the first inorganic compound and the second inorganic compound in a light-emitting layer of the light-emitting element according to the first embodiment along an arbitrary straight line.

FIG. 9 is a graph showing concentration distributions of indium sulfide and zinc sulfide in the light-emitting layer illustrated in FIG. 8, measured using X-ray photoelectron spectroscopy.

FIG. 10 is a cross-sectional view illustrating another example of a direction of measurement of concentrations of the first inorganic compound and the second inorganic compound in the light-emitting layer of the light-emitting element according to the first embodiment along an arbitrary straight line.

FIG. 11 is a graph showing concentration distributions of indium sulfide and zinc sulfide in the light-emitting layer illustrated in FIG. 10 measured using XPS.

FIG. 12 is an explanatory diagram illustrating a method for examining concentration distributions of the first inorganic compound and the second inorganic compound contained in the light-emitting layer of the light-emitting element according to the first embodiment in a film thickness direction using cross-sectional TEM/EDX.

FIG. 13 is another explanatory diagram illustrating the method for examining the concentration distributions of the first inorganic compound and the second inorganic compound contained in the light-emitting layer of the light-emitting element according to the first embodiment in the film thickness direction using cross-sectional TEM/EDX.

FIG. 14 is a graph showing concentration distributions of indium sulfide and zinc sulfide of the light-emitting layer in the film thickness direction illustrated in FIG. 12, measured using cross-sectional TEM/EDX.

FIG. 15 is a cross-sectional view illustrating another example of a schematic configuration of a light-emitting element according to the first embodiment.

FIG. 16 is a cross-sectional view illustrating still another example of a schematic configuration of a light-emitting element according to the first embodiment.

FIG. 17 is a cross-sectional view illustrating yet another example of a schematic configuration of a light-emitting element according to the first embodiment.

FIG. 18 is a cross-sectional view illustrating a further example of a schematic configuration of a light-emitting element according to the first embodiment.

FIG. 19 is a cross-sectional view illustrating a still further example of a schematic configuration of a light-emitting element according to the first embodiment.

FIG. 20 is a cross-sectional view illustrating a yet further example of a schematic configuration of a light-emitting element according to the first embodiment.

FIG. 21 is a cross-sectional view illustrating a still more example of a schematic configuration of a light-emitting element according to the first embodiment.

FIG. 22 is a flowchart illustrating an example of a method for manufacturing the light-emitting element according to the first embodiment.

FIG. 23 illustrates schematic cross-sectional views for describing a ligand substitution step in a quantum dot dispersion manufacturing step illustrated in FIG. 22.

FIG. 24 is a schematic cross-sectional view illustrating a step subsequent to the ligand substitution step in the quantum dot dispersion manufacturing step.

FIG. 25 illustrates examples of step cross-sectional views of some steps in a light-emitting layer forming step illustrated in FIG. 22.

FIG. 26 is a diagram schematically showing a reaction scheme for manufacturing the first inorganic compound.

FIG. 27 is a graph showing thermal decomposability of zinc xanthate and results of measurement by TGA.

FIG. 28 is a graph showing results of measurement using a film thickness step profiler during deposition of a first film of the light-emitting element according to the present embodiment.

FIG. 29 is a cross-sectional view illustrating an example of formation of a first layer formed in a first film forming step illustrated in FIG. 22.

FIG. 30 is a cross-sectional view illustrating another example of formation of a first layer formed in the first film forming step illustrated in FIG. 22.

FIG. 31 is a cross-sectional view illustrating still another example of formation of a first layer formed in the first film forming step illustrated in FIG. 22.

FIG. 32 is a step cross-sectional view illustrating an example of one step in the light-emitting layer forming step illustrated in FIG. 22.

FIG. 33 is another step cross-sectional view illustrating an example of one step in the light-emitting layer forming step illustrated in FIG. 22.

FIG. 34 is a diagram showing a reaction scheme for forming a metal sulfide from a precursor of the metal sulfide when the matrix material contains the metal sulfide as an inorganic compound.

FIG. 35 is a cross-sectional view illustrating an example of a schematic configuration of a light-emitting element according to a modified example of the first embodiment.

FIG. 36 is a cross-sectional view illustrating an example of a schematic configuration of a light-emitting element according to a second embodiment.

FIG. 37 is a flowchart illustrating an example of a method for manufacturing the light-emitting element according to the second embodiment.

FIG. 38 is a plan view illustrating a configuration example of a display device according to a third embodiment.

### DESCRIPTION OF EMBODIMENTS

### First Embodiment

Hereinafter, one embodiment of the disclosure will be described in detail. Note that, in the following, description of “from A to B” for two numbers A and B means “being equal to or greater than A and equal to or less than B”, unless otherwise specified. Further, in the following, a layer formed in a process prior to that of a layer being compared is referred to as a “lower layer”, and a layer formed in a process after that of a layer being compared is referred to as an “upper layer”.

In the following, for convenience of description, members having the same functions as the members described earlier may be denoted by the same reference numerals and signs, and the description thereof will not be repeated. Differences from the embodiment described above will be described in the embodiment described below. It goes without saying that similar modifications to those of the embodiment described above can be made even unless otherwise explained.

### Overall Configuration of Light-Emitting Element

A light-emitting element according to the present embodiment includes a first electrode and a second electrode, and a light-emitting layer located between the first electrode and the second electrode, and the light-emitting layer contains multiple quantum dots and a matrix material. Note that in the following, the light-emitting layer may be referred to as “EML”, the quantum dot may be referred to as “QD”, and the matrix material may be referred to as “MX”.

One of the first electrode and the second electrode is an anode electrode and another is a cathode electrode. In the disclosure, layers between the first electrode and the second electrode are referred to as function layers. At least the EML is included as a function layer.

The light-emitting element according to the present embodiment may be a single-layer type including only one EML as a function layer, or may be a multi-layer type including multiple function layers as function layers. Between the first electrode and the EML and/or between the second electrode and the EML, for example, a charge transport layer may be located as a function layer. The charge transport layer may be a hole transport layer or an election transport layer. Hereinafter, the charge transport layer may be referred to as “CTL”, the hole transport layer may be referred to as “HTL”, and the electron transport layer may be referred to as “ETL”. The light-emitting element may optionally further include layers such as a hole injection layer, an electron blocking layer, a hole blocking layer, and an electron injection layer. Hereinafter, the hole injection layer may be referred to as “HIL”.

The light-emitting element may have a conventional structure in which the anode electrode is a lower layer electrode and the cathode electrode is an upper layer electrode, or may have an inverted structure in which the cathode electrode is a lower layer electrode and the anode electrode is an upper layer electrode.

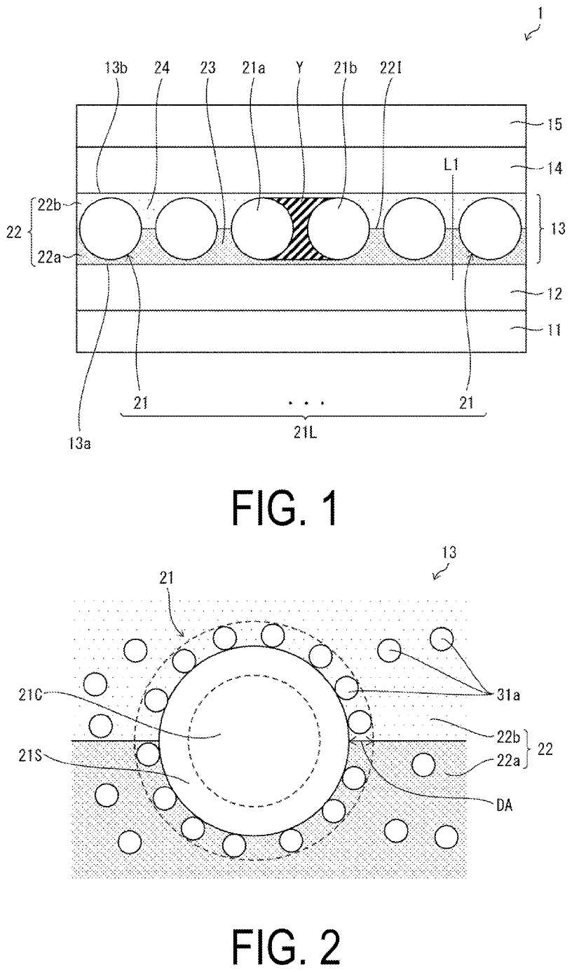

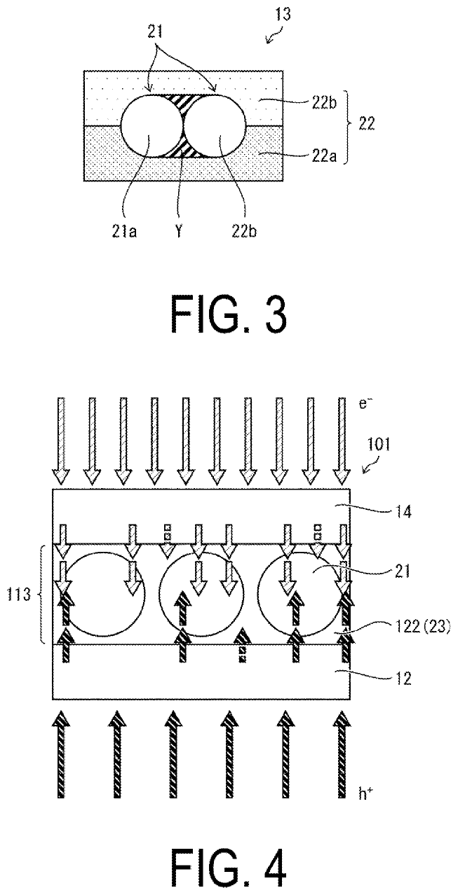

FIG. 1 is a cross-sectional view illustrating an example of a schematic configuration of a light-emitting element 1 according to the present embodiment. FIG. 2 is a cross-sectional view illustrating an example of a schematic configuration of a QD 21 and its vicinity in the light-emitting element 1 illustrated in FIG. 1. FIG. 3 is a cross-sectional view illustrating a state in which adjacent QDs 21 are close to each other in the light-emitting element 1 illustrated in FIG. 1.

As illustrated in FIG. 1, the light-emitting element 1 includes an anode electrode 11 and a cathode electrode 15 facing each other, and an EML 13 located between the anode electrode 11 and the cathode electrode 15. As illustrated in FIG. 1, an HTL 12 may optionally be located between the anode electrode 11 and the EML 13. In addition, an ETL 14 may optionally be located between the cathode electrode 15 and the EML 13.

The anode electrode 11 is an electrode that supplies holes to the EML 13 when a voltage is applied. The cathode electrode 15 is an electrode that supplies electrons to the EML 13 when a voltage is applied. The anode electrode 11 and the cathode electrode 15 each contain a conductive material, and are connected to a power supply (not illustrated) (e.g., a direct current power supply), so that a voltage is applied therebetween.

At least one of the anode electrode 11 and the cathode electrode 15 is a light-transmissive electrode. Note that either the anode electrode 11 or the cathode electrode 15 may be a so-called reflective electrode having light reflectivity. In the light-emitting element 1, light can be extracted from the side of the light-transmissive electrode.

For example, in a case where the light-emitting element 1 is a top-emission type light-emitting element that emits light from an upper layer electrode side, a light-transmissive electrode is used as the upper layer electrode, and a reflective electrode is used as the lower layer electrode. On the other hand, in a case where the light-emitting element 1 is a bottom-emission type light-emitting element that emits light from a lower layer electrode side, a light-transmissive electrode is used as the lower layer electrode, and a reflective electrode is used as the upper layer electrode.

For the light-transmissive electrode, for example, a conductive light-transmissive material that transmits visible light, such as indium tin oxide (ITO), indium zinc oxide (IZO), zinc oxide (ZnO), aluminum-doped zinc oxide (AZO), boron-doped zinc oxide (BZO), or fluorine-doped tin oxide (FTO), is used.

For the reflective electrode, for example, a conductive light reflective material having high reflectivity for visible light, for example, a metal such as aluminum (Al), copper (Cu), gold (Au), or silver (Ag), or an alloy containing these metals, such as a magnesium-silver alloy (MgAg), is suitably used. Note that the reflective electrode may be provided by layering a layer made of the light-transmissive material and a layer made of the light-reflective material.

The HTL 12 is a charge transport layer that contains a hole transport material and has a hole transport function of transporting holes injected from the anode electrode 11 to the EML 13. As the hole transport material, a known organic material or a known inorganic material employed for the HTL in a quantum dot light emitting diode (QLED), which is a light-emitting element containing QDs, an organic light-emitting diode (OLED), or the like can be used.

Examples of organic materials used for the HTL 12 include conductive compounds such as poly[(9,9-dioctylfluorenyl-2,7-diyl)-co-(4,4′-(N-4-sec-butylphenyl))diphenylamine)](TFB), poly(4-butyltriphenylamine) (p-TPD), 4,4′-bis(carbazol-9-yl)biphenyl (CBP), polyphenylenevinylene (PPV), a composite of poly(3,4-ethylenedioxythiophene) (PEDOT) and polystyrene sulfonic acid (PSS) (PEDOT:PSS), TFB(poly[(9,9-dioctylfluorenyl-2,7-diyl)-co-(4,4′-(N-4-sec-butylphenyl)diphenylamine)]), and polyvinyl carbazole (PVK).

Examples of inorganic materials used for the HTL 12 include metal oxides such as molybdenum oxides (MoO₂ and MoO₃), nickel oxide (NiO), chromium oxide (Cr₂O₃), magnesium oxide (MgO), magnesium zinc oxide (MgZnO), lanthanum nickel oxide (LaNiO₃), and tungsten oxide (WO₃). In particular, materials having high electron affinity and ionization potential are suitable for the material of the HTL 12.

The ETL 14 is a charge transport layer that contains an electron transport material and has an electron transport function of transporting electrons injected from the cathode electrode 15 to the EML 13. As the electron transport material, for example, a known organic or a known inorganic material employed for the ETL in a QLED, an OLED, or the like can be used.

Examples of organic materials used for the ETL 14 include conductive compounds such as tris(8-quinolinol)aluminum complex (Alq3), bathocuproine (BCP), and (2-(4-biphenylyl)-5-(4-tert-butylphenyl)-1,3,4-oxadiazole) (t-Bu-PBD).

Examples of inorganic materials used for the ETL 14 include metal oxides such as zinc oxide (ZnO), aluminum zinc oxide (AlZnO), lithium zinc oxide (LiZnO), and magnesium zinc oxide (MgZnO). In particular, materials having low electron affinity are suitable for the material of the ETL 14.

The EML 13 includes multiple QDs 21 and an MX 22. In the EML 13, a hole transported from the anode electrode 11 and an electron transported from the cathode electrode 15 recombine, and a resulting exciton emits light during a process of transitioning from a conduction band level to a valence band level of the QD 21. The EML 13 includes nano-sized QDs 21 corresponding to emission colors as luminescent materials.

The QD 21 is a dot having a particle maximum width of 100 nm or less. The QD 21 may be generally called a semiconductor nanoparticle because its composition is derived from a semiconductor material. The QD 21 may be generally called an inorganic nanoparticle because its composition is derived from an inorganic material. The QD 21 may be called a nanocrystal because its structure has a specific crystal structure, for example.

The shape of the QD 21 is not particularly limited as long as it is within a range satisfying the maximum width, and the shape thereof is not limited to a spherical three-dimensional shape (circular cross-sectional shape). The shape of the QD 21 may be, for example, a polygonal cross-sectional shape, a rod-shaped three-dimensional shape, a branch-shaped three-dimensional shape, or a three-dimensional shape having unevenness on the surface thereof, or a combination of these.

The QD 21 may include at least one metal element. Examples of the metal element included in the QD 21 include Cd, Zn, In, Sb, Al, Si, Ga, Pb, Ge, and Mg. The QD 21 may be a semiconductor material in which at least one metal element and a non-metal element such as S, Te, Se, N, P, or As are combined.

The QD 21 may be formed only of a core, and may be of a two-component core type, of a three-component core type, or of a four-component core type. As illustrated in FIG. 2, the QD 21 may have a core-shell structure including a core 21C and a shell 21S, and may be a core-shell type or a core-multi-shell type.

As illustrated in FIG. 2, when the QD 21 includes the shell 21S, the core 21C may be located in a center part, and the shell 21S may be located on a surface of the core 21C. The shell 21S desirably covers the entire core 21C, but it is not necessary for the shell 21S to completely cover the core 21C. The shell 21S may be formed on part of the surface of the core 21C. The QD 21 can be said to have the core-shell structure when it is found that the shell 21S is formed on part of the surface of the core 21C, or it is found that the shell 21S envelopes the core 21C, in an observation of a cross-section of the QD 21. Accordingly, it is sufficient to observe a cross-section of the QD 21 to determine that the shell 21S covers the entire core 21C. Note that the cross-sectional observation can be performed by, for example, a scanning transmission electron microscope (STEM) or a transmission electron microscope (TEM).

The QD 21 may also include doped nanoparticles or have a compositionally graded structure. The shell 21S may be formed in a state of being solid-solved on the surface of the core 21C. In FIG. 2, a boundary between the core 21C and the shell 21S is indicated by a dotted line, which indicates that it does not matter whether the boundary between the core 21C and the shell 21S can be confirmed by analysis. The shell 21S may be formed from multiple layers.

In the QD 21, materials of the core 21C and the shell 21S may contain materials used for the core material and the shell material of known QDs, respectively. The core 21C can be made of, for example, Si, Ge, CdSe, CdS, CdTe, InP, GaP, InN, ZnSe, ZnS, ZnTe, CdSeTe, GaInP, ZnSeTe, or the like. The shell 21S can be made of, for example, CdS, ZnS, CdSSe, CdTeSe, CdSTe, ZnSSe, ZnSTe, ZnTeSe, AIP, or the like. As an example, when the shell 21S contains ZnSSe, ZnSSe contained in the shell 21S may be ZnSₓSe₁₋ₓ (0≤x≤1). When the QD 21 has the core-shell structure, examples of materials for the QD 21 (combination of materials of core 21C/shell 21S) include ZnSe/ZnS, InP/ZnS, CdSe/CdS, CdSe/ZnSe, and CIGS/ZnS.

Note that compositions shown in chemical formulas in the disclosure are representative examples. Composition ratios shown in the chemical formulas are desirably stoichiometry in which actual compositions of compounds are the same as the chemical formulas. However, it does not exclude that the actual composition of the compound is other than stoichiometric.

An emission wavelength of the QD 21 can be changed in various ways depending on, for example, a particle size and composition thereof. The QD 21 is a QD that emits visible light, and the emission wavelength can be controlled from a blue wavelength region to a red wavelength region by appropriately adjusting the particle size and composition of the QD 21.

The core 21C of the QD 21 is a luminescent material that has a valence band level and a conduction band level, and emits light by recombination of a hole in the valence band level with an electron in the conduction band level. Light emitted from the QD 21 has a narrower spectrum due to a quantum confinement effect, making it possible to obtain the emitted light with relatively deep chromaticity.

Note that the QDs 21 in the EML 13 do not need to be regularly arranged as illustrated in FIG. 1, and the QDs 21 may be included in the EML 13 in a disorderly manner. In the EML 13, the QDs 21 may be in a state in which the MX 22 is formed between the adjacent QDs 21 and the QDs 21 are not close to each other as illustrated in FIG. 1, or the EML 13 may include two or more QDs 21 close to each other as illustrated in FIG. 3. Note that a layer thickness of the EML 13 is not limited and may be set in the same manner as in a known example.

The MX 22 is an MX that is mainly made of inorganic compounds (inorganic media), and includes two or more types of inorganic compounds including at least an inorganic compound 23 and an inorganic compound 24 as inorganic compounds. Note that in the following description, the inorganic compound 23 is referred to as a first inorganic compound, and the inorganic compound 24 is referred to as a second inorganic compound, but the present embodiment is not limited thereto. The MX 22 may be an inorganic matrix material (inorganic MX) composed of inorganic compounds.

In the disclosure, the MX means a member that contains and holds other components, and can be rephrased as a parent material, a base material, or a filler material. That is, in the disclosure, the MX 22 refers to a member that contains and holds the QDs 21. The MX 22 is an element that constitutes a film in which the QDs 21 are dispersed, and is one of constituent elements of the EML 13 including the multiple QDs 21 as illustrated in FIG. 1. Note that the MX 22 may be solid at room temperature.

The EML 13 may be filled with the MX 22. Paying attention to two QDs 21 among the multiple QDs 21 as illustrated in FIG. 1, the MX 22 may fill a space between the two QDs 21 (i.e., a region Y (space) between the two QDs 21). When the two QDs 21 are defined as a first QD 21a and a second QD 21b, respectively, the region Y is, in a cross-sectional view, a region surrounded by two straight lines (common tangents) tangent to circumferences of the first QD 21a and the second QD 21b and facing circumferences of the first QD 21a and the second QD 21b.

Note that FIG. 1 illustrates an example in which the QDs 21 are embedded in the MX 22 with spaces therebetween. However, as described above, in the EML 13, the adjacent QDs 21 may be either not close to each other or close to each other. As illustrated in FIG. 3, even when the first QD 21a and second QD 21b adjacent to each other are close to each other, the region Y (space) may exist between the first QD 21a and second QD 21b. Even when the first QD 21a and the second QD 21b are close to each other, the MX 22 may fill the region Y (space) between the first QD 21a and the second QD 21b.

Thus, the MX 22 may fill a region (space) in the EML 13 other than the QDs 21. Accordingly, the MX 22 may fill a region (space) in the EML 13 other than the QDs 21. The EML 13 may include a quantum dot group (QD group) including the multiple QDs 21, and the MX 22 may fill a region (space) in the EML 13 other than the QD group. Here, three or more QDs 21 are collectively referred to as the QD group. The MX 22 may fill a region (space) in the EML 13 other than the multiple QDs 21. As illustrated in FIG. 1, an outer edge part 13a on an anode electrode 11 side (first outer edge part) and an outer edge part 13b on a cathode electrode 15 side (second outer edge part) in the EML 13 may be covered with the MX 22. Part of the MX 22 may be located from the outer edge part 13a or the outer edge part 13b of the EML 13, and the QDs 21 may be located away from at least one of the outer edge part 13a and the outer edge part 13b of the EML 13. However, a configuration of the light-emitting element 1 is not limited to the above configuration, and at least one of the outer edge part 13a and the outer edge part 13b of the EML 13 may not be formed only by the MX 22, and parts of the QDs 21 may be exposed from the MX 22. The MX 22 may represent a portion in the EML 13 excluding the QDs 21.

Note that in the present embodiment, the outer edge part 13a in the EML 13 on the anode electrode 11 side indicates an interface between the EML 13 and the HTL 12, which is an adjacent layer on the anode electrode 11 side, in the EML 13. The outer edge part 13b in the EML 13 on the cathode electrode 15 side indicates an interface between the EML 13 and the ETL 14, which is an adjacent layer on the cathode electrode 15 side, in the EML 13.

The MX 22 may contain the multiple QDs 21. The MX 22 may be formed so as to fill spaces between the multiple QDs 21 (i.e., spaces formed between the multiple QDs 21). The MX 22 may partially or completely fill the spaces between the multiple QDs 21.

The MX 22 may include a continuous film having an area of 1000 nm² or more along a plane direction orthogonal to a layer thickness direction. The continuous film means a film that is not separated by a material other than a material constituting the continuous film in one plane. The continuous film may be an integral film that is seamlessly connected by chemical bonds of the material that constitutes the MX 22.

The MX 22 may be made of a material different from a material of the shell 21S included in each of the multiple QDs 21, or may contain the same material as the shell 21S. In other words, the shell 21S may contain only a material different from at least one type of inorganic compound contained in the MX 22, or may contain the same material as at least one type of inorganic compound contained in the MX 22. When the shell 21S contains the same material as at least one type of inorganic compound contained in the MX 22, the inorganic compound may be the inorganic compound 23, may be the inorganic compound 24, or may be an inorganic compound other than the inorganic compound 23 and the inorganic compound 24. When the shell 21S contains the same material as at least one type of inorganic compound contained in the MX 22, an effect of confining carriers is high, so that diffusion of excitons from the QDs 21 to the MX 22 can be suppressed, thereby improving luminous efficiency. Further, since the shell 21S and at least one type of inorganic compound contained in the MX 22 is continuously connected, quality of the MX 22 can be improved.

As described above, when the MX 22 contains the same material as the shell 21S, an average distance between adjacent cores 21C (core-to-core distance) may be 3 nm or more, or may be 5 nm or more, to avoid contact between the QDs 21 and to avoid aggregation of the QDs 21. Alternatively, the average distance between the adjacent cores 21C may be 0.5 times or more an average core diameter. The core-to-core distance is an average of distances between 20 adjacent cores 21C in a space containing 20 cores. The core-to-core distance may be kept wider than a distance when the shells 21S are in contact with each other. The average core diameter is obtained by averaging the core diameters of 20 cores 21C in the cross-sectional observation in a space containing the 20 cores. The core diameter can be the diameter of a circle having the same area as the core area in the cross-sectional observation.

A concentration of the MX 22 in the EML 13 is, for example, an area ratio occupied by the MX 22 in a cross section of the EML 13. The concentration of the MX 22 may be 10% or more and 90% or less, or may be 30% or more and 70% or less in the cross-sectional observation of the EML 13. The concentration of the MX 22 may be measured, for example, from an area ratio in image processing in the cross-sectional observation of the EML 13. When the QD 21 has the core-shell structure, a concentration of the shell 21S may be 1% or more and 50% or less. When the shells 21S and the MX 22 are made of the same material (same composition) and the shells 21S and the MX 22 cannot be distinguished from each other, a concentration of a combined region of the shells 21S and the MX 22 may be within a numerical range obtained by adding a numerical range of the concentration of the shells 21S to a numerical range of the concentration of the MX 22. Ratios of the cores 21C and the shells 21S of the QDs 21 and the MX 22 may be appropriately adjusted so that the sum of these ratios is 100% or less. Thus, when the shells 21S and the MX 22 cannot be distinguished from each other, the shells 21S may be part of the MX 22.

The EML 13 may be composed of the multiple QDs 21 and the MX 22. When the EML 13 is analyzed, an intensity of carbon detected by a chain structure may be a noise level or less.

A constituent material of the MX 22 desirably has a band gap (hereinafter referred to as “Eg”) wider (larger) than a constituent material of the QD 21. For example, as described above, when the QD 21 includes the core 21C and the shell 21S, the Eg of at least one type of inorganic compound contained in the MX 22 is desirably larger than an Eg of the core 21C or the shell 21S.

Recombination of carriers (electrons and holes) injected into the QD 21 occurs mainly in the core 21C. The shell 21S has functions of suppressing generation of defects, dangling bonds, or the like in the core 21C and reducing recombination of carriers through a deactivation process. When the Eg of the MX 22 is larger than the Eg of the core 21C or the shell 21S, an effect of confining excitons in the core 21C is high, and excitons generated by carrier recombination or light absorption in the core 21C are less likely to diffuse into the MX 22, thereby improving luminous efficiency of the light-emitting element 1.

Note that the Eg of at least one type of inorganic compound contained in the MX 22 may be equal to the Eg of the shell 21S or smaller than the Eg of the shell 21S as long as the Eg of the MX 22 is larger than the Eg of the core 21C. However, the Eg of at least one type of inorganic compound contained in the MX 22 is preferably larger than the Eg of the shell 21S. In this case, the effect of confining the excitons in the core 21C is higher, which suppresses diffusion of the excitons from the QD 21 to the MX 22, thereby further improving luminous efficiency.

At least one type of inorganic compound (inorganic material) contained in the MX 22 may be a semiconductor material or may be an insulator material. Examples of at least one type of inorganic compound contained in the MX 22 suitably include a metal sulfide. A precursor of the metal sulfide thermally decomposes at a relatively low temperature, and an Eg of the precursor of the metal sulfide can be easily controlled. Therefore, the MX 22 preferably contains a metal sulfide as an inorganic compound, and the inorganic compound 23 and the inorganic compound 24 are preferably metal sulfides.

Examples of the metal sulfides include tin sulfide (SnS₂), indium sulfide (In₂S₃), zinc sulfide (ZnS), aluminum sulfide (Al₂S₃), beryllium sulfide (BeS), germanium sulfide (GeS₂), barium sulfide (BaS), calcium sulfide (CaS), and magnesium sulfide (MgS).

However, the inorganic compound is not limited to these metal sulfides, and may be an inorganic compound other than metal sulfides. Examples of inorganic compounds other than metal sulfides include metal selenides, metal tellurides, metal oxides, and other inorganic compounds containing, for example, Group IV elements (to be specific, Group 16 elements in the notation based on the new IUPAC system).

Examples of the metal selenides include beryllium selenide (BeSe), barium selenide (BaSe), calcium selenide (CaSe), and magnesium selenide (MgSe). Examples of the metal tellurides include calcium telluride (CaTe) and magnesium telluride (MgTe). Examples of the metal oxides include zinc oxide (ZnO).

Note that the MX 22 may contain two or more types of inorganic compounds including at least the inorganic compound 23 and the inorganic compound 24, and does not exclude addition of materials different from these inorganic compounds as additives.

As described above, in the EML 13, the MX 22 fills spaces around the QDs 21. Thus, in the light-emitting element 1, the QDs 21 are covered with the MX 22 so that the QDs 21 are protected by the MX 22.

The MX, which contains an inorganic compound as an inorganic medium, is less likely to peel off from the QDs 21 than organic ligands, and the QDs can be strongly protected by covering the QDs 21 with the MX 22. Therefore, when the EML 13 includes the MX 22, which contains an inorganic compound, stability of the EML 13 can be improved compared to when organic ligands are used in the EML 13. In addition, deterioration of the QDs 21 can be suppressed, thereby improving luminescence characteristics and reliability of the light-emitting element 1.

However, when the QDs 21 are uniformly covered with an inorganic compound, using an inorganic compound having a large Eg as the inorganic compound reduces the efficiency of carrier injection of holes and electrons into the QDs 21, resulting in reduced luminous efficiency. Therefore, in the present embodiment, as described above, two or more types of inorganic compounds including the inorganic compound 23 and the inorganic compound 24 are used for the MX 22, and the composition of the MX 22 of the EML 13 is made different in the layer thickness direction. This makes energy levels of the MX 22 different between the HTL 12 side and the ETL 14 side.

The MX 22 has a first region containing at least the inorganic compound 23 and a second region containing at least the inorganic compound 24 in a direction of a straight line L1 passing through the outer edge part 13a and the outer edge part 13b in the EML 13. The second region is located closer to the outer edge part 13b than the first region. A concentration of the inorganic compound 23 in the first region is different from a concentration of the inorganic compound 23 in the second region by at least a certain amount. For example, it is desirable that the concentration of the inorganic compound 23 in the first region be different from the concentration of the inorganic compound 23 in the second region by 20% or more.

That is, the MX 22 has, in the direction of the straight line L1, (1) the first region containing at least the inorganic compound 23 and (2) the second region containing at least the inorganic compound 24, located closer to the outer edge part 13b than the first region, and in which the concentration of the inorganic compound 23 is different from the concentration of the inorganic compound 23 in the first region by at least a certain amount. Note that when the concentration of the inorganic compound 23 in the second region is different from the concentration of the inorganic compound 23 in the first region by at least a certain amount, a concentration of the inorganic compound 24 in the second region is also different from a concentration of the inorganic compound 24 in the first region by at least a certain amount.

The MX 22 has the first region containing at least the inorganic compound 23 and the second region containing at least the inorganic compound 24 in the direction of the straight line L1 passing through the outer edge part 13a and the outer edge part 13b in the EML 13.

The concentration of the inorganic compound 23 in the first region is greater than the concentration of the inorganic compound 24 in the first region, and the concentration of the inorganic compound 24 in the second region is greater than the concentration of the inorganic compound 23 in the second region.

FIG. 1 illustrates an example in which the MX 22 has, as the first region, a first layer 22a mainly composed of the inorganic compound 23 and, as the second region, a second layer 22b mainly composed of the inorganic compound 24.

Note that, unless otherwise specified or contradictory, in the cross-sectional observation of the EML 13, a structure of the MX 22 is observed with a width of about 100 nm, and it is sufficient that it is found to have the desired structure, and it is not necessary for the desired structure to be observed throughout the entire EML 13.

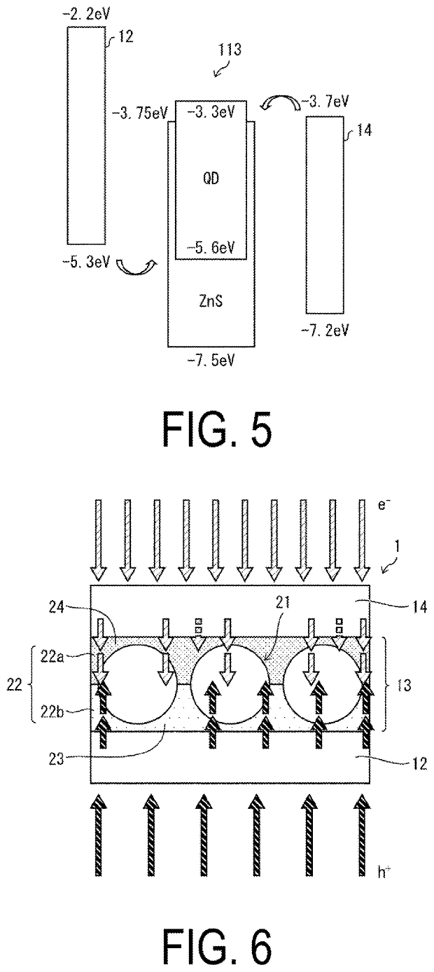

FIG. 4 is a cross-sectional view schematically illustrating a state of carrier injection in a comparative light-emitting element 101 in which the QDs 21 are uniformly covered with an MX 122 composed of the inorganic compound 23. In FIG. 4, the numbers of holes (h⁺) and electrons (e⁻) are indicated by arrows. In FIG. 4, illustration of components other than the HTL 12, an EML 113, and the ETL 14 are omitted. FIG. 5 is a diagram illustrating energy band structures of the function layers in a comparative light-emitting element 101 illustrated in FIG. 4.

The comparative light-emitting element 101 has the same configuration as the light-emitting element 1 illustrated in FIG. 1 except that the EML 13 is replaced with the EML 113 in which the QDs 21 are covered with the MX 122 composed of the inorganic compound 23.

FIG. 4 illustrates an example in which the anode electrode 11 is made of ITO, the HTL 12 is made of p-TPD, the ETL 14 is made of ZnMgO, and the cathode electrode 15 is made of Al. In such light-emitting element 101, as illustrated in FIGS. 4 and 5, when zinc sulfide (ZnS) is used for the inorganic compound 23 and the QDs 21 are uniformly covered with ZnS, balance between electrons and holes in the EML 113 is, for example, about 6:4. Thus, in this case, electrons are excessive and holes are deficient, which reduces carrier balance, thereby reducing luminous efficiency and reliability.

Therefore, in such a case of electron excess and hole deficiency, it is desirable to reduce an amount of electrons to be injected or increase an amount of holes to be injected in the EML 113 in order to improve the carrier balance. In the present embodiment, in such a case of electron excess and hole deficiency, it is preferable to use (I) an inorganic compound, as the inorganic compound 23, having an element composition ratio that has an energy level or characteristics that more easily promote hole injection than the inorganic compound 24, or to use (II) an inorganic compound, as the inorganic compound 24, having an element composition ratio that has an energy level or characteristics that more easily suppress electron injection than the inorganic compound 23. By satisfying at least one of the conditions (I) and (II), the carrier balance can be adjusted, and thus the light-emitting element 1 having high stability, high luminous efficiency, and high reliability can be provided.

Therefore, in the case of electron excess and hole deficiency as described above, for example, it is desirable to use, as the inorganic compound 24, an inorganic compound having a larger Eg than the inorganic compound 23. In other words, it is desirable to use, as the inorganic compound 23, an inorganic compound having a smaller Eg than the inorganic compound 24. In this case, the injection of electrons is suppressed to adjust the carrier balance, thereby improving luminous efficiency and reliability.

In the case of electron excess and hole deficiency as described above, for example, it is preferable to use, as the inorganic compound 23, an inorganic compound having a higher hole mobility than the inorganic compound 24. In other words, it is preferable to use, as the inorganic compound 24, an inorganic compound having a lower hole mobility than the inorganic compound 23. In this case, the injection of holes is facilitated to adjust the carrier balance, thereby improving luminous efficiency and reliability.

The carrier mobility such as the hole mobility or the electron mobility is calculated by the following equation (A).

$$μ = e τ / {m}^{*} \qquad ( A )$$

In the equation (A), e represents a charge, r represents a mean free time (scattering time), and m* represents an effective mass.

Assuming that the charge e and the mean free time r are constant, the smaller the effective mass, the higher the carrier mobility.

Therefore, when it is desired to improve hole injection properties, it is desirable to use, as the inorganic compound 23, an inorganic compound that generally has a larger Eg and a smaller hole effective mass than ZnS, which is used as the material of the shell 21S of the QD 21.

Table 1 shows examples of Eg and effective mass of metal sulfides having relatively high hole transport properties as inorganic compounds having relatively high hole transport properties. Table 2 shows examples of Eg and effective mass of metal sulfides having relatively low hole transport properties as inorganic compounds having relatively low hole transport properties.

TABLE 1

| Inorganic compound | | Effective |
|---|---|---|
| (metal sulfide) | Eg (eV) | mass |
| Sn_{S}2 | 1.99 | 0.55 |
| In₂S₃ | 2.30 | 0.29 |
| ZnS | 3.51 | 0.71 |
| Al₂S₃ | 4.00 | 0.53 |
| BeS | 4.17 | 0.56 |

TABLE 2

| Inorganic compound | | Effective |
|---|---|---|
| (metal sulfide) | Eg (eV) | mass |
| GeS₂ | 3.52 | 0.88 |
| BaS | 3.90 | 2.30 |
| CaS | 5.78 | 1.24 |
| MgS | 6.39 | 0.95 |

Thus, in the case of electron excess and hole deficiency as described above, for example, it is possible that (a) the inorganic compound 23 is indium sulfide (InS) and the inorganic compound 24 is magnesium sulfide (MgS). Alternatively, it is possible that (b) the inorganic compound 23 is zinc sulfide (ZnS) and the inorganic compound 24 is magnesium sulfide (MgS). Alternatively, it is possible that (c) the inorganic compound 23 is indium sulfide (InS) and the inorganic compound 24 is zinc sulfide (ZnS). Note that examples of the indium sulfide (InS) include In₂S₃.

Thus, in the case of electron excess and hole deficiency, for example, by changing the MX 22 on the HTL 12 side (to be specific, the inorganic compound 23) to the MX 22 mainly composed of an inorganic compound having a smaller Eg and higher hole mobility (smaller hole effective mass) than the MX 22 on the ETL 14 side (to be specific, the inorganic compound 24), the hole injection can be promoted and the electron excess can be adjusted. In addition, for example, by changing the MX 22 on the ETL 14 side to the MX 22 mainly composed of an inorganic compound having a larger Eg and a lower carrier mobility (larger effective mass) than the MX 22 on the HTL 12 side, the electron injection can be suppressed and the hole deficiency can be adjusted.

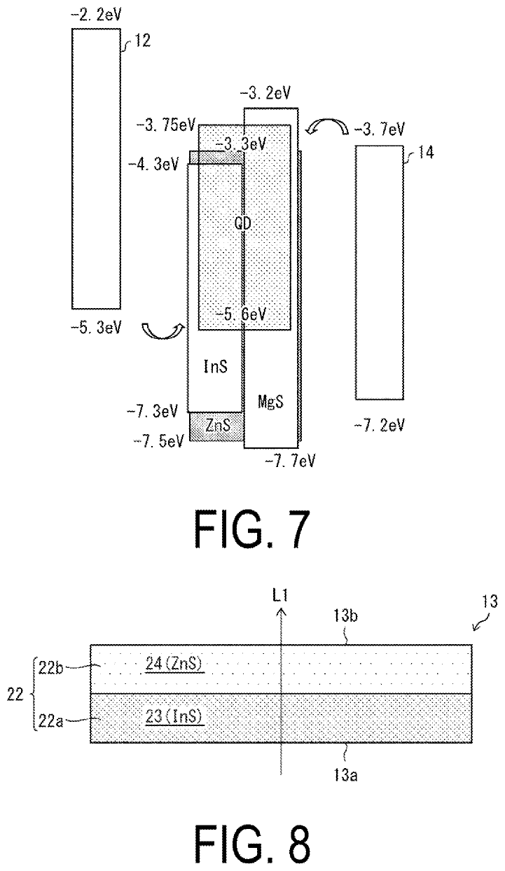

FIG. 6 is a cross-sectional view schematically illustrating, as an example, a state of carrier injection in the light-emitting element 1 when (a) the inorganic compound 23 is indium sulfide (In₂S₃) and the inorganic compound 24 is magnesium sulfide (MgS). In FIG. 6, illustration of components other than the HTL 12, the EML 13, and the ETL 14 are omitted. Similar to the light-emitting element 101, FIG. 6 illustrates an example in which the anode electrode 11 is made of ITO, the HTL 12 is made of p-TPD, the ETL 14 is made of ZnMgO, and the cathode electrode 15 is made of Al. Also in FIG. 6, as in FIG. 4, the numbers of holes (h⁺) and electrons (e⁻) are indicated by arrows. FIG. 7 is a diagram illustrating energy band structures of function layers in the light-emitting element 1 illustrated in FIG. 6. Note that for comparison, FIG. 7 also illustrates an energy band structure of zinc sulfide (ZnS).

As illustrated in FIGS. 6 and 7, by locating the first layer 22a on the HTL 12 side, which is mainly composed of In₂S₃, which has a smaller Eg than ZnS, hole injection into the QDs 21 can be promoted more than when the QDs 21 are covered with only ZnS. In addition, by locating the second layer 22b on the ETL 14 side, which is mainly composed of MgS, which has a larger Eg than ZnS, electrons to be injected into the QDs 21 can be suppressed more than when the QDs 21 are covered with only ZnS. In this case, the balance between electrons and holes in the EML 13 can be improved to about 5:5, thus adjusting the carrier balance.

Note that FIG. 6 illustrates an example in which (a) the inorganic compound 23 is In₂S₃ and the inorganic compound 24 is MgS. However, also when (b) the inorganic compound 23 is ZnS and the inorganic compound 24 is MgS and when (c) the inorganic compound 23 is InS such as In₂S₃ and the inorganic compound 24 is ZnS, the balance of electrons and holes can be improved to about 5:5.

On the other hand, in a case of electron deficiency and hole excess, in order to improve the carrier balance, it is desirable to reduce an amount of holes to be injected or increase an amount of electrons to be injected. Therefore, in such a case of electron deficiency and hole excess, it is desirable to use (i) an inorganic compound, as the inorganic compound 23, having an element composition ratio that has an energy level or characteristics that more easily suppress holes than the inorganic compound 24, or to use (ii) an inorganic compound, as the inorganic compound 24, having an element composition ratio that has an energy level or characteristics that more easily promote electron injection than the inorganic compound 23. By satisfying at least one of the conditions (i) and (ii), the carrier balance can be adjusted, and thus the light-emitting element 1 having high stability, high luminous efficiency, and high reliability can be provided.

Thus, in the case of electron deficiency and hole excess as described above, it is desirable to use, as the inorganic compound 23, for example, an inorganic compound having a larger Eg than the inorganic compound 24. In other words, it is desirable to use, as the inorganic compound 24, an inorganic compound having a smaller Eg than the inorganic compound 23. In this case, the injection of holes is suppressed to adjust the carrier balance, thereby improving luminous efficiency and reliability.

In the case of electron deficiency and hole excess as described above, it is desirable to use, as the inorganic compound 24, for example, an inorganic compound having a higher electron mobility than the inorganic compound 23. In other words, it is desirable to use, as the inorganic compound 23, an inorganic compound having a lower electron mobility than the inorganic compound 24. In this case, the injection of electrons is facilitated to adjust the carrier balance, thereby improving luminous efficiency and reliability.

Therefore, in the case of electron deficiency and hole excess, for example, by changing the MX 22 on the ETL 14 side to the MX 22 mainly composed of an inorganic compound that has a smaller Eg and a higher electron mobility (smaller electron effective mass) than the MX 22 on the HTL 12 side, the electron injection can be promoted and the hole excess can be adjusted. In addition, for example, by changing the MX 22 on the HTL 12 side to the MX 22 mainly composed of an inorganic compound having a larger Eg and a lower electron mobility (larger electron effective mass) than the MX 22 on the ETL 14 side, the electron injection can be promoted and the hole excess can be adjusted.

In Tables 1 and 2, the Eg and the effective mass when the inorganic compounds constituting the MX 22 are metal sulfides are shown as examples. However, as described above, the inorganic compounds constituting the MX 22 may be inorganic compounds other than metal sulfides, such as metal selenides, metal tellurides, and metal oxides.

Thus, Table 3 shows, as inorganic compounds having relatively high hole transport properties, examples of the Eg and the effective mass of inorganic compounds other than metal sulfides that have relatively high hole transport properties. Table 4 shows, as inorganic compounds having relatively low hole transport properties, examples of the Eg and the effective mass of inorganic compounds other than metal sulfides having relatively low hole transport properties.

TABLE 3

| Inorganic | | Effective |
|---|---|---|
| compound | Eg (eV) | mass |
| BeSe | 3.62 | 0.47 |
| CaTe | 4.06 | 0.69 |
| MgTe | 4.69 | 0.12 |
| ZnO | 3.37 | 0.59 |

TABLE 4

| Inorganic | | Effective |
|---|---|---|
| compound | Eg (eV) | mass |
| BaSe | 3.60 | 1.77 |
| CaSe | 4.86 | 0.96 |
| MgSe | 5.63 | 0.81 |

For example, as shown in Tables 1 to 4, different inorganic compounds have different energy levels. Thus, according to the present embodiment, by making the composition of the MX 22 different in the first region and the second region as described above, the transport capabilities of holes and electrons can be changed.

In the present embodiment, the concentration of the inorganic compound 23 in the first region is greater than the concentration of the inorganic compound 24 in the first region, and the concentration of the inorganic compound 24 in the second region is greater than the concentration of the inorganic compound 23 in the second region.

Thus, according to the present embodiment, the MX 22 contains the inorganic compound 23 and the inorganic compound 24, and the concentrations of the inorganic compound 23 and the inorganic compound 24 in the EML 13 are changed between the outer edge part 13a and the outer edge part 13b in the MX 22, so that the carrier balance can be adjusted to improve luminous efficiency. Therefore, according to the present embodiment, it is possible to provide the light-emitting element 1 having high stability, high luminous efficiency, and high reliability.

In the present embodiment, a concentration of an inorganic compound is defined by a ratio of elements constituting the inorganic compound. The concentration of an inorganic compound can be determined by analysis using X-ray photoelectron spectroscopy (XPS).

In the analysis by non-destructive testing (e.g., XPS analysis), amounts and ratios of constituent elements in an inorganic compound are basically detected separately. For example, when the inorganic compound contained in the MX 22 is ZnS, Zn and S are detected separately in the analysis by non-destructive testing. In this case, the ratio of Zn:S in the detected elements is 1:1. This indicates that the inorganic compound contained in the first region is ZnS.

On the other hand, it is assumed that, for example, the MX 22 contains two types of inorganic compounds and these inorganic compounds are both sulfides. At this time, when the inorganic compounds contained in the MX 22 are ZnS and In₂S₃, the elements detected by the above analysis are three types of Zn, In, and S. In this case, when a concentration of ZnS is equal to a concentration of In₂S₃ (i.e., ZnS:In₂S₃=1:1), Zn:In:S is detected as 1:2:4.

However, when a combination ratio of these inorganic compounds (e.g., a combination ratio of the inorganic compound 23 and the inorganic compound 24) is complicated, it becomes difficult to identify these inorganic compounds. Thus, in the actual detection method using XPS in this case, only the element amounts and the element ratios of Zn and In are actually compared. Then, whether the inorganic compound containing the detected element is a sulfide such as ZnS or an oxide such as ZnO is indirectly inferred from other elements.

Note that in this case, whether the inorganic compound is ZnS or ZnO may be confirmed, for example, from the energy of the chemical bond detected by the above detection method (inspection method), or the above detection method may be combined with another detection method. As the above detection method, as described above, analysis by XPS has the highest priority, but as an analysis method with the second highest priority after XPS, cross-sectional TEM/EDX using a cross-sectional transmission electron microscope (TEM) and energy dispersive X-ray spectroscopy (EDX) may be used. For example, analysis may be performed by combining XPS with an inspection method such as cross-sectional TEM/EDX. As an analysis method with priority next to the cross-sectional TEM/EDX, analysis of a crystal form such as X-ray diffraction (XRD) may be performed. For example, analysis may be performed by combining XPS with an inspection method such as XRD.

The concentrations of the inorganic compounds contained in the MX 22 are measured along the arbitrary straight line L1 passing through the outer edge part 13a (first outer edge part) on the anode electrode 11 side and the outer edge part 13b (second outer edge part) on the cathode electrode 15 side in the EML 13. The concentrations of the inorganic compounds contained in the MX 22 are detected (measured) as the concentrations of the inorganic compounds contained in a measurement plane in the EML 13 perpendicular to the straight line L1.

When XPS is used to measure the above concentrations, the measurement is performed at multiple measurement depths in a depth direction of the EML 13. In XPS, a sample is sputter-etched with argon (Ar) ions accelerated to several hundred V to several kV, while an exposed sample surface is irradiated with X-rays, and kinetic energy of photoelectrons emitted from the sample surface is measured. Thus, the composition and the chemical bonding state of elements constituting the sample surface are analyzed.

Therefore, when XPS is used to measure the concentrations, each measurement surface is an X-ray irradiated surface, and the size and shape of the X-ray irradiation spot are the size and shape of the measurement surface. Thus, all measurement surfaces have the same area and the same shape. The concentrations of the inorganic compound 23 and the inorganic compound 24 are measured under the same conditions along the arbitrary straight line L1 passing through the outer edge part 13a and the outer edge part 13b.

FIG. 8 is a cross-sectional view illustrating an example of a direction of measurement of concentrations of the inorganic compound 23 and the inorganic compound 24 in the EML 13 along the arbitrary straight line L1. Note that in FIG. 8, for convenience of illustration, illustration of the QDs 21 is omitted. FIG. 8 illustrates an example in which the MX 22 has, as the first region, the first layer 22a mainly composed of the inorganic compound 23 and, as the second region, the second layer 22b mainly composed of the inorganic compound 24, in which the inorganic compound 23 is InS and the inorganic compound 24 is ZnS. In FIG. 8, the straight line L1 is indicated by an arrow to indicate the measurement direction.

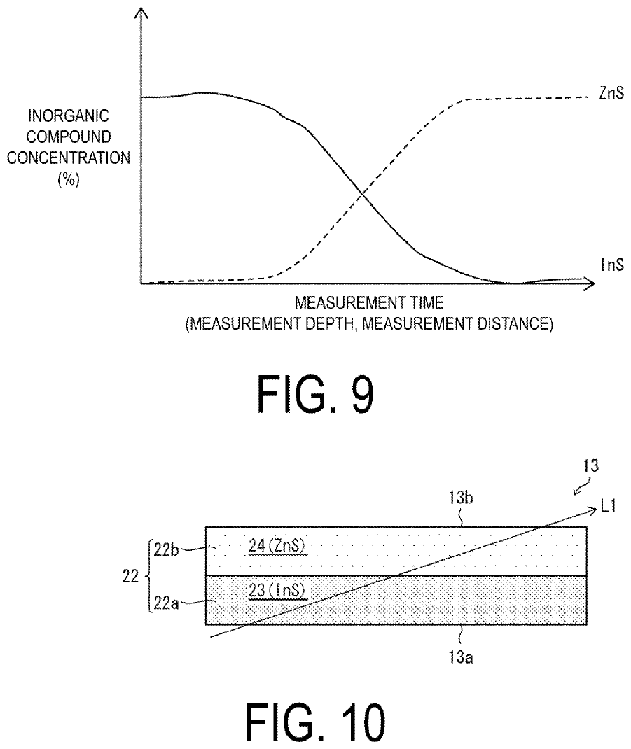

FIG. 9 is a graph showing concentration distributions of InS (e.g., In₂S₃) and ZnS in the EML 13 illustrated in FIG. 8, measured along the straight line L1 illustrated in FIG. 8 using XPS. Note that for convenience of explanation and illustration, FIG. 9 shows an example of measurement results when no QDs 21 are present on the arbitrary straight line L1. However, when the QDs 21 are present on the straight line L1, the concentrations of the inorganic compound 23 and the inorganic compound 24 may be obtained by interpolation. In FIG. 9, the measurement time is proportional to the measurement depth (measurement distance) along the straight line L1 illustrated in FIG. 8. Therefore, in FIG. 9, the measurement time can be replaced with the measurement depth (measurement distance) along the straight line L1.

As shown in FIG. 9, XPS can be used to quantify elements at any measurement depth (measurement distance) in the EML 13 (in other words, elements at any measurement plane). For example, the ZnS concentration can be calculated as the Zn element concentration by the following equation.

ZnS concentration (=Zn element concentration)=(Zn element amount)/{(Zn element amount)+(In element amount)}Similarly, the InS concentration can be calculated as the In element concentration by the following equation.

InS concentration (=In element concentration)=(In element amount)/{(Zn element amount)+(In element amount)}

Thus, the concentration distribution of each of the inorganic compounds at any measurement depth (measurement distance) in the EML 13 can be examined from the element concentration at any measurement depth (measurement distance) in the EML 13.

The measurement results shown in FIG. 9 indicate that a boundary exists between the inorganic compound 23 (InS) and the inorganic compound 24 (ZnS) in the EML 13. That is, it can be seen that there is a portion in the EML 13 where the concentrations of the inorganic compound 23 (InS) and the inorganic compound 24 (ZnS) are equal. This shows that there are regions of different inorganic compounds in the EML 13. While FIG. 8 illustrates a case in which the MX 22 is completely divided into the first region and the second region, this is just an example. For example, since the first region is a region mainly composed of the inorganic compound 23 and the second region is a region mainly composed of the inorganic compound 24, the first region and the second region do not necessarily need to be in complete contact with each other and may exist with a gap therebetween.

When there is a portion in the first region where the concentration of the inorganic compound 23 is different by a certain amount (e.g., 20%) or more, that is, when there is a portion where the concentration of the inorganic compound 23 is 100% and a portion where the concentration of the inorganic compound 23 is 80%, for example, it can be considered that the change in the concentration of the inorganic compound 23 in that portion is large. Therefore, it can be considered that a boundary exists in that portion. Similarly, when there is a portion in the second region where the concentration of the inorganic compound 24 is different by a certain amount (e.g., 20%) or more, it can be considered that a boundary exists in that portion. When there is a portion in the first region where the concentration of the inorganic compound 23 is different by a certain amount (e.g., 20%) or more and further, there is a portion in the second region where the concentration of the inorganic compound 24 is different by a certain amount (e.g., 20%) or more, then a boundary may be considered to exist. They show that there are regions of different inorganic compounds in the EML 13.

FIG. 10 is a cross-sectional view illustrating another example of a direction of measurement of the concentrations of the inorganic compound 23 and the inorganic compound 24 in the EML 13 along the arbitrary straight line L1. Note that also in FIG. 10, for convenience of illustration, illustration of the QDs 21 is omitted. Also FIG. 10 illustrates an example in which the MX 22 has, as the first region, the first layer 22a mainly composed of the inorganic compound 23 and, as the second region, the second layer 22b mainly composed of the inorganic compound 24, in which the inorganic compound 23 is InS and the inorganic compound 24 is ZnS. Also in FIG. 10, the straight line L1 is indicated by an arrow to indicate the measurement direction.

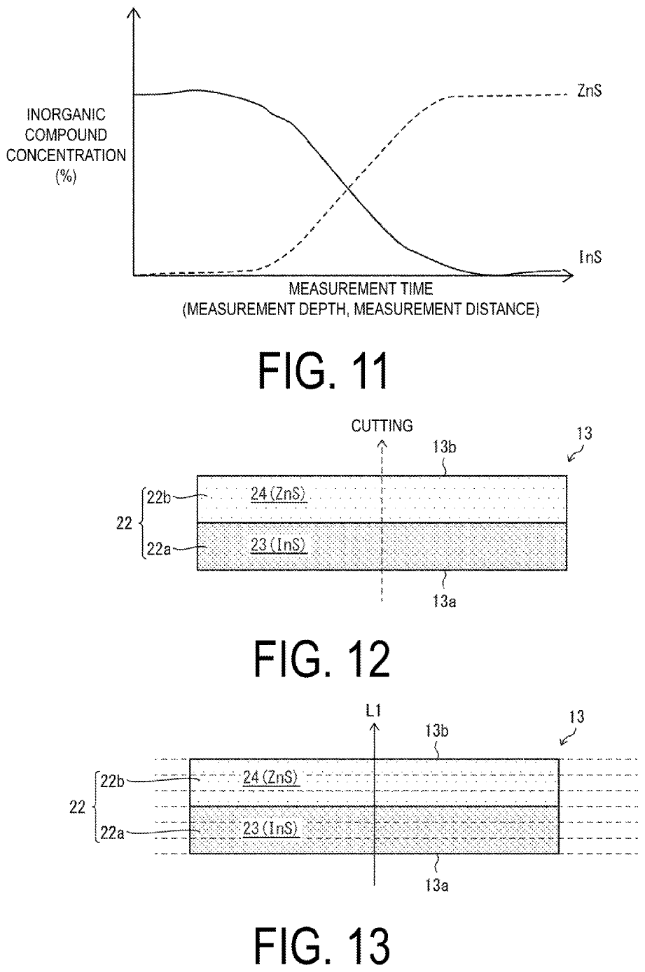

FIG. 11 is a graph showing concentration distributions of InS and ZnS in the EML 13 illustrated in FIG. 11, measured along the straight line L1 illustrated in FIG. 10 using XPS. Note that for convenience of explanation and illustration, also FIG. 10 shows an example of measurement results when no QDs 21 are present on the arbitrary straight line L1.

As can be seen from FIGS. 8 to 11, even when the same measurement method is used, a direction of the straight line L1, that is, a penetration path of Ar ions and X-rays may be perpendicular to the layer surface of the EML 13 as illustrated in FIG. 8, or may be oblique to the layer surface of the EML 13 as illustrated in FIG. 10.

In the present embodiment, the concentration distributions of the inorganic compounds in the EML 13 can be measured by the above-described method using XPS. However, in the present embodiment, the method is not limited to the method using XPS, and the concentration distributions of the inorganic compounds contained in the EML 13 may be measured using cross-sectional TEM/EDX. Note that the measurement results using XPS take precedence over the measurement results using cross-sectional TEM/EDX. FIGS. 12 and 13 are explanatory diagrams illustrating a method for examining the concentration distributions of the inorganic compound 23 and the inorganic compound 24 contained in the EML 13 in the film thickness direction using cross-sectional TEM/EDX. Note that also in FIGS. 12 and 13, for convenience of illustration, illustration of the QDs 21 is omitted. Also FIGS. 12 and 13 illustrate an example in which the MX 22 has, as the first region, the first layer 22a mainly composed of the inorganic compound 23, and, as the second region, the second layer 22b mainly composed of the inorganic compound 24, in which the inorganic compound 23 is InS and the inorganic compound 24 is ZnS. Also in FIG. 13, the straight line L1 is indicated by an arrow to indicate the measurement direction.

When examining the concentration distributions of the inorganic compound 23 and the inorganic compound 24 contained in the EML 13 in the film thickness direction using cross-sectional TEM/EDX, first, as illustrated in FIG. 12, the light-emitting element 1 is processed using focused ion beam (FIB) or the like to form a cross section of the EML 13 along the layer thickness direction of the EML 13. Subsequently, as illustrated in FIG. 13, the cross section of the EML 13 is observed by a cross-sectional TEM, and scanned by EDX in a direction perpendicular to the layer thickness direction (direction perpendicular to the straight line L1) along dotted lines illustrated in FIG. 13 in multiple times, and the numbers of the elements contained in the MX 22 on all scanned measurement lines are counted. When the device has a function for counting the number of elements on the measurement line, the counting may be performed using that function. When the device does not have that function, the counting may be performed by image analysis of an EDX scan image. This makes it possible to quantify the amounts (concentrations) of elements of each inorganic compound distributed in the above cross section of the EML 13 in a direction of the straight line L1. In this case, an area scanned by EDX (i.e., an area scanned by X-rays) in the cross section is the size and shape of each measurement line. Therefore, also in this case, all measurement line have the same shape.

When cross-sectional TEM/EDX is used to measure the concentrations of the inorganic compounds contained in the EML 13 in this manner, the concentration of each of the inorganic compounds contained in the MX 22 in the EML 13 at each measurement surface in the layer thickness direction (direction of the straight line L1) can be calculated based on the above-described calculation equations. For example, the ZnS concentration can be calculated as the Zn element concentration by the following equation.

ZnS concentration (=Zn element concentration)=(Zn element amount)/{(Zn element amount)+(In element amount)}Similarly, the InS concentration can be calculated as the In element concentration by the following equation.

InS concentration (=In element concentration)=(In element amount)/{(Zn element amount)+(In element amount)}

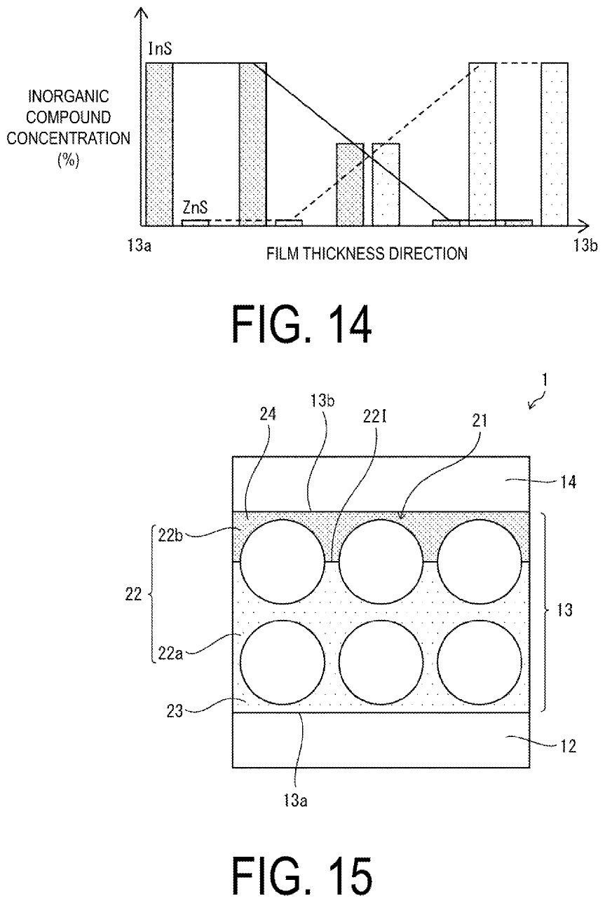

FIG. 14 is a graph showing the concentration distributions of InS and ZnS of the EML 13 in the film thickness direction (direction of the straight line L1) illustrated in FIG. 12, measured using cross-sectional TEM/EDX. Note that as described above, FIG. 14 shows the concentrations of InS and ZnS in the MX 22.

As described above, in the light-emitting element 1 according to the present embodiment, as an example, the MX 22 has, as the first region, the first layer 22a mainly composed of the inorganic compound 23, and includes, as the second region, the second layer 22b mainly composed of the inorganic compound 24.

The inorganic compound 23 and the inorganic compound 24 permeate and mix with each other at an interface between the first layer 22a and the second layer 22b, for example, resulting in concentration distributions in the layer thickness direction of the EML 13 as shown in FIGS. 9, 11, and 14.

At this time, the concentration of the inorganic compound 23 may change continuously or stepwise in the direction of the straight line L1. Similarly, the concentration of the inorganic compound 24 may change continuously or stepwise in the direction of the straight line L1.

When a medium having a large Eg is inserted into an interface between the EML 13 and a layer adjacent to the EML 13, all carriers need to overcome a barrier of the medium. However, by continuously or stepwise changing the concentration of the inorganic compound 23 or the inorganic compound 24, a carrier injection barrier can be changed stepwise, so that carrier injection can be performed more easily compared to the case in which a large injection barrier is overcome all at once. Therefore, by having concentration distributions of the inorganic compound 23 and the inorganic compound 24 in the EML 13 in this manner, drive voltage can also be reduced.

However, as described above, the light-emitting element 1 may have two or more regions between the outer edge part 13a and the outer edge part 13b in which the concentrations of the inorganic compounds constituting the MX 22 are different by at least a certain amount in the layer thickness direction of the EML 13. As described above, the inorganic compounds desirably have concentration distributions in the layer thickness direction of the EML 13. However, the disclosure does not exclude that the concentration difference of the inorganic compound in the first layer 22a and the second layer 22b is 100%. That is, the first layer 22a may contain only the inorganic compound 23, and the second layer 22b may contain only the inorganic compound 24.

It is desirable that the EML 13 have, within a range of at least 1 nm from the outer edge part 13a, a region in which the concentration of the inorganic compound 23 in the MX 22 is 80% or more. When the MX 22 near the outer edge part 13a is formed of a relatively uniform component in this manner, carriers can be easily injected from the anode electrode 11 side into the QDs 21 near the outer edge part 13a.

Similarly, it is desirable that the EML 13 have, within a range of at least 1 nm from the outer edge part 13b, a region in which the concentration of the inorganic compound 24 in the MX 22 is 80% or more. When the MX 22 near the outer edge part 13b is formed of a relatively uniform component in this manner, carriers can be easily injected from the cathode electrode 15 side into the QDs 21 near the outer edge part 13b.

Note that when the EML 13 has, within the range of at least 1 nm from the outer edge part 13a, a region in which the concentration of the inorganic compound 23 in the MX 22 is 80% or more in this manner, the outer edge part 13a is preferably covered with the MX 22 as illustrated in, for example, FIG. 1 and the like. Similarly, when the EML 13 has, within the range of at least 1 nm from the outer edge part 13b, a region in which the concentration of the inorganic compound 24 in the MX 22 is 80% or more, the outer edge part 13b is preferably covered with the MX 22 as illustrated in, for example, FIG. 1 and the like. In other words, it is preferable that parts of the MX 22 be located from the outer edge part 13a and the outer edge part 13b of the EML 13, and the QDs 21 are located away from the outer edge part 13a and the outer edge part 13b of the EML 13.

The concentrations of the inorganic compound 23 and the inorganic compound 24, as well as the layer thicknesses of the first layer 22a and the second layer 22b, can be changed as desired by utilizing volume changes that occur when these inorganic compounds are formed from thermolytic or photodegradable precursors.

Thus, the interface between the first region and the second region may intersect with the multiple QDs 21. For example, in the light-emitting element 1 illustrated in FIG. 1, the EML 13 has one quantum dot row 21L (QD row) in the layer thickness direction of the EML 13, in which multiple QDs 21 are arranged in a direction perpendicular to the layer thickness direction of the EML 13. In the light-emitting element 1 illustrated in FIG. 1, an interface 221 between the first layer 22a and the second layer 22b intersects with the QD row 21L.

In the light-emitting element 1, the concentration of each of the inorganic compounds contained in the MX 22 can be changed within a range of a thickness of one QD 21 in the layer thickness direction of the EML 13. Therefore, even when only one QD 21 is stacked in the layer thickness direction of the EML 13 (i.e., one layer), such as when the QDs 21 are stacked in only one row in the layer thickness direction of the EML 13, as illustrated in FIG. 1, or even when the QDs 21 are not stacked in an orderly manner, the carrier balance can be adjusted, thereby improving the luminous efficiency.

Thus, by making inorganic compounds having any Eg in direct contact with the QDs 21 in the EML 13 on a particle-by-particle basis at any ratio, an effect of the inorganic compounds can be exerted more effectively.

Note that as described above, FIG. 1 is an example of the schematic configuration of the light-emitting element 1 according to the present embodiment. The light-emitting element 1 according to the present embodiment is not limited to the configuration illustrated in FIG. 1. FIGS. 15 to 21 are cross-sectional views illustrating other examples of the light-emitting element 1 according to the present embodiment. Note that in FIGS. 15 to 21, illustrations of components other than the HTL 12, the EML 13, and the ETL 14 are omitted.

As illustrated in FIG. 15, multiple (e.g., two) QD rows 21L may be arranged in the layer thickness direction of the EML 13. That is, QDs 21 may be stacked in multiple layers in the layer thickness direction of the EML 13. In this case, the interface 221 between the first layer 22a and the second layer 22b may intersect with the QD row 21L on the HTL 12 side, in other words, the lowermost QD row 21L, as illustrated in FIG. 1, for example. The interface 221 between the first layer 22a and the second layer 22b may intersect with the QD row 21L located above the lowermost QD row 21L (on the ETL 14 side), as illustrated in FIG. 15. To be specific, for example, when two layers of the QDs 21 are stacked as illustrated in FIG. 15, the interface 221 between the first layer 22a and the second layer 22b may be located about 1.5 layers of the QDs 21.

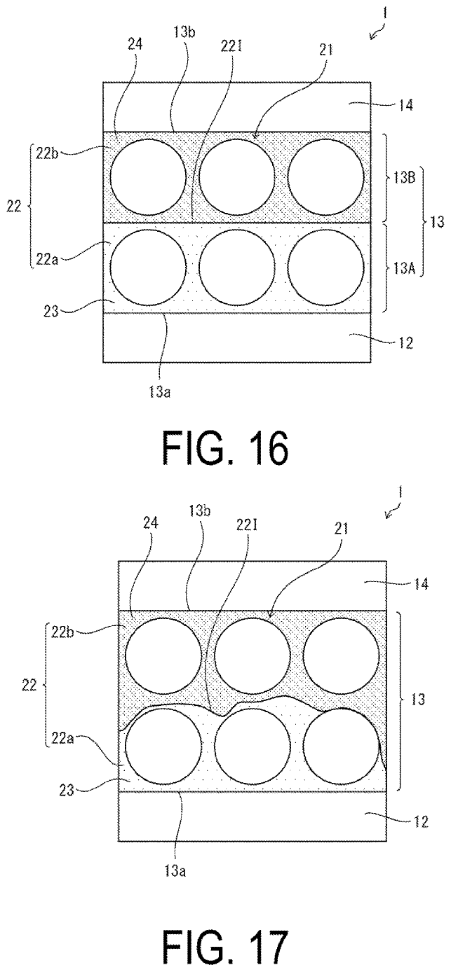

As illustrated in FIG. 16, the first layer 22a and the second layer 22b may each contain QDs 21. Therefore, in the light-emitting element 1, as illustrated in FIG. 16, the EML 13 may include an EML 13A (first light-emitting layer) and an EML 13B (second light-emitting layer), the first layer 22a may be used for the EML 13A, and the second layer 22b may be used for the EML 13B. Thus, the EML 13A may contain the inorganic compound 23 and the QDs 21, and the EML 13B may contain the inorganic compound 24 and the QDs 21. In this case, the QDs 21 contained in the EML 13A and the QDs 21 contained in the EML 13B may be the same as or different from each other.

As illustrated in FIG. 17, the EML 13 has multiple QD rows 21L stacked in the layer thickness direction of the EML 13, but may have a configuration in which the interface 221 between the first layer 22a and the second layer 22b is not clearly separated.

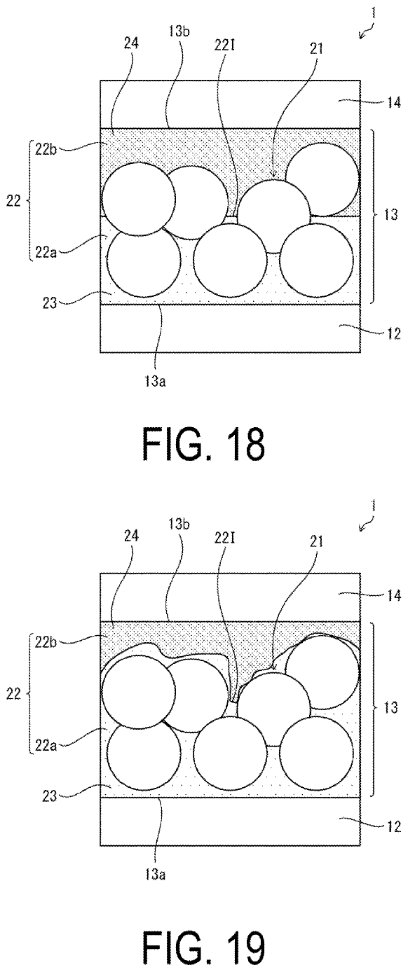

The QDs 21 do not have to be contained in the EML 13 in an aligned state as the QD rows 21L. As illustrated in FIG. 18, the QDs 21 may be stacked in a complex manner within the EML 13. Also in this case, the interface 221 between the first layer 22a and the second layer 22b may intersect with the QD row 21L above the lowermost QD row 21L (on the ETL 14 side). For example, when two layers of the QDs 21 are stacked, the interface 221 between the first layer 22a and the second layer 22b may be located at about 1.5 layers of the QDs 21. Although not illustrated, the interface 221 may intersect with the QD row 21L on the HTL 12 side, in other words, the lowermost QD row 21L.

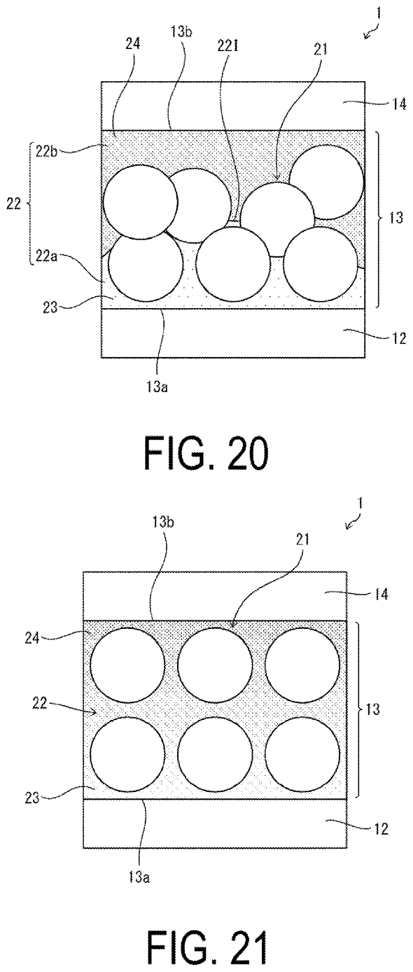

Further, as illustrated in FIG. 19, the EML 13 may have a configuration in which only the first layer 22a contains the QDs 21 and the second layer 22b does not contain the QDs 21, or as illustrated in FIG. 20, the second layer 22b may contain at least some QDs 21. FIG. 19 illustrates an example in which the QDs 21 are stacked in a complex manner within the EML 13, the interface 221 between the first layer 22a and the second layer 22b is not clearly separated, and the QDs 21 are contained only in the first layer 22a, while the QDs 21 are not contained in the second layer 22b. FIG. 20 illustrates an example in which the QDs 21 are stacked in a complex manner within the EML 13, the interface 221 between the first layer 22a and the second layer 22b is not clearly separated, and the interface 221 between the first layer 22a and the second layer 22b intersects with the lowermost QD row 21L in some portions and intersects with the QD row 21L above the lowermost QD row 21L (on the ETL 14 side) in other portions.

As illustrated in FIG. 21, in the EML 13, concentrations of multiple inorganic compounds may have gradations, and the concentration of each of the inorganic compounds may gradually change from the outer edge part 13a to the outer edge part 13b to have an element gradient.

Thus, the interface between the first region and the second region may be located at the center of the EML 13 in the thickness direction as illustrated in FIG. 1, or may be located on the HTL 12 side (in other words, on the anode electrode 11 side) or the ETL 14 side (in other words, on the cathode electrode 15 side) relative to the center of the EML 13 in a thickness direction.

As illustrated in FIGS. 18 to 20, the QDs 21 may be exposed from the MX 22 at least at one of the outer edge part 13a and the outer edge part 13b of the EML 13.

For example, as illustrated in FIGS. 18 to 20, part of the MX 22 may be located from at least one of the outer edge part 13a and the outer edge part 13b of the EML 13, and the QDs 21 may be located away from at least one of the outer edge part 13a and the outer edge part 13b.

In any case, by using inorganic compounds having different energy levels on the HTL 12 side and the ETL 14 side in the EML 13, it is possible to form the EML 13 in which both holes and electrons are easily transported and easily injected to the QDs 21.

The MX 22 may further contain at least one type of halogen element in addition to the inorganic compound 23 and the inorganic compound 24. For example, as illustrated in FIG. 2, the MX 22 may contain halide ions 31a including at least one type of fluoride ion (F⁻), chloride ion (Cl⁻), bromide ion (Br⁻), and iodide ion (I⁻).

As illustrated in FIG. 2, when the halide ions 31a are present in the vicinity of a surface of the QD 21, dispersibility of the QDs 21 is improved. Thus, the MX 22 desirably contains halogen elements. Note that an area having about a thickness of the shell 21S may be considered to be the vicinity of the surface of the QD 21.

The halogen elements are stabilized by bonding with unpaired electrons of the inorganic compounds that constitute the MX 22. Thus, when the MX 22 contains halogen elements, defects in the MX 22 can be inactivated. Note that, here, “defects in the MX 22 is inactivated” means that the unpaired electrons are used for bonding with the halogen elements, and thus the defects no longer function as non-luminescent centers or carrier traps.

The MX 22 may contain 1 atom % or more of the halogen elements. A concentration of halide ions 31a in the vicinity of each QD 21 is preferably higher than a concentration of halide ions 31a in a surrounding area relative to the vicinity of each QD 21. For example, an area around a certain QD 21 that is within a distance of 1 nm from the outermost surface of the QD 21 may be defined as the vicinity of the quantum dot.

Thus, for example, as illustrated in FIG. 2, in the area around the QD 21, the mean value of concentrations of the sum of halogen atoms within a distance DA of 1 nm or less from an outer surface of the shell 21S, which is the outermost surface of the QD 21, may be higher than the mean value of concentrations of the sum of the halogen atoms at the other positions. In this case, the mean value of the concentrations of the sum of the halogen atoms within the distance DA of 1 nm may be 10% or more, 50% or more, or 100% or more higher than the mean value of the concentrations of the sum of the halogen atoms at the other positions. Such a concentration distribution can be confirmed by, for example, element mapping by cross-sectional transmission electron microscope-energy dispersive X-ray spectroscopy (TEM-EDX).

Here, the “other positions” can also be said to be positions where no QD 21 exists within 1 nm. Multiple QDs 21 are included in the EML 13. Thus, it can be said that the above value is a value obtained by comparing the mean value of the concentrations of the sum of the halogen atoms in a range of the surrounding 1 nm of each of the QDs 21 in the EML 13 with the mean value of the concentrations of the sum of the halogen atoms in the portions away from any QD 21 in the EML 13 beyond 1 nm.

That is, the mean value of the concentrations of the sum of the halogen elements in the region within 1 nm from the outermost surface of each of the multiple QDs 21 in the MX 22 is preferably higher than the mean value of the concentrations of the sum of the halogen elements in the region at a distance exceeding 1 nm from the outermost surface of each of the multiple QDs 21 in the MX 22, and may be, for example, 10% or more, 50% or more, or 100% or more higher.

Thus, the dispersibility of the QDs 21 can be further improved, thereby forming the EML 13 having a more uniform thickness.

The MX 22 can contain the halide ions by forming the EML 13 using a QD dispersion containing halogen elements and the QDs 21.

### Method for Manufacturing Light-Emitting Element 1

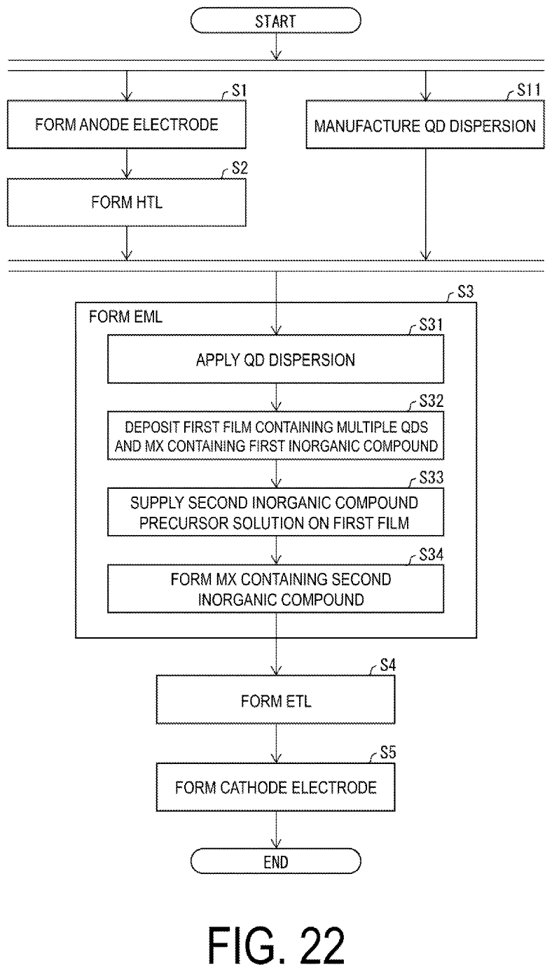

Next, a method for manufacturing the light-emitting element 1 according to the present embodiment will be described with reference to FIGS. 22 to 34. FIG. 22 is a flowchart illustrating an example of the method for manufacturing the light-emitting element 1 according to the present embodiment.

As illustrated in FIG. 22, in the method for manufacturing the light-emitting element 1 according to the present embodiment, first, the anode electrode 11 is formed on a substrate as a support body (step S1: anode electrode forming step). Subsequently, the HTL 12 is formed (step S2: hole transport layer (HTL) forming step). In parallel, a QD dispersion is manufactured (prepared) (step S11: quantum dot (QD) dispersion manufacturing step). Subsequently, the EML 13 is formed using the QD dispersion (step S3: light-emitting layer (EML) forming step). Subsequently, the ETL 14 is formed (step S4: electron transport layer (ETL) forming step). Subsequently, the cathode electrode 15 is formed (step S5: cathode electrode forming step). In this way, the light-emitting element 1 is manufactured.

For formation of the anode electrode 11 in step S1 and for formation of the cathode electrode 15 in step S5, for example, vapor deposition technique, sputtering technique, or the like is used.

For formation of the HTL 12 in step S2 and formation of the ETL 14 in step S4, for example, a vacuum vapor deposition technique, a sputtering technique, a coating technique using colloidal solution, or a sol-gel technique is used.

Here, before describing step S3, step S11 will be described.

### Step S11

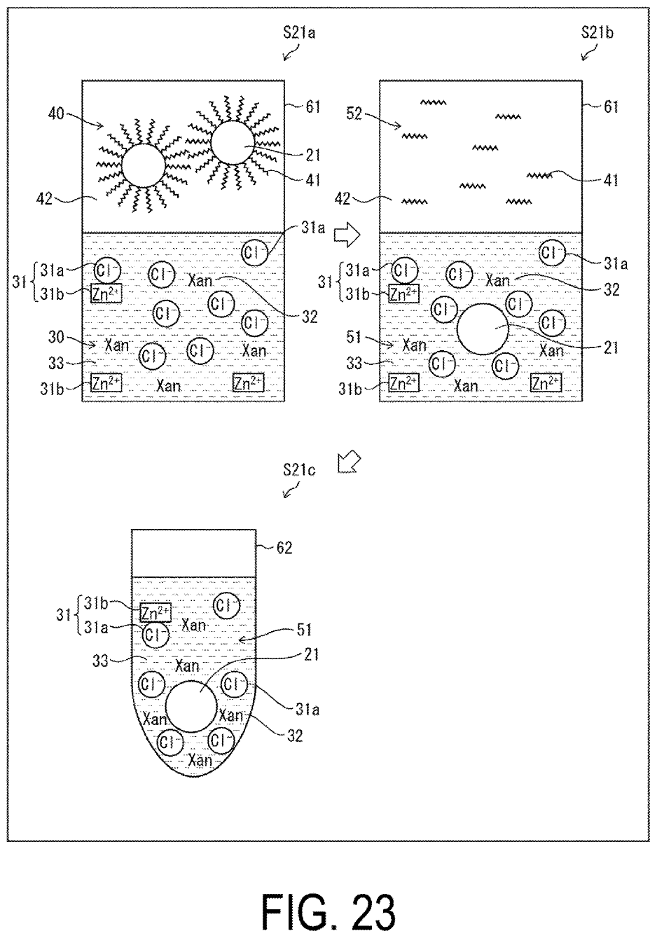

A QD dispersion preparation step, which is step S11, includes a ligand substitution step (step S21) of substituting ligands coordinated to the QDs 21, as illustrated in FIG. 23. FIG. 23 illustrates schematic cross-sectional views for describing the ligand substitution step (step S21) in step S11.

In many cases, organic ligands (hereinafter, for convenience of explanation, referred to as “first organic ligands”) are coordinated to synthesized or commercially obtained QDs, as ligands. Commercially available QDs are commonly provided in a form of a QD dispersion that contains the first organic ligands as ligands. The first organic ligands are used as dispersants to improve dispersibility of the QDs in the QD dispersion, and are also used to improve surface stability and storage stability of the QDs. For example, a wet method is used to synthesize the QDs, and a particle size of the QD is controlled by coordinating the first organic ligands to a surface of the QD. Therefore, the QD dispersion synthesized by the wet method contains, for example, the first organic ligands used to synthesize the QDs. Such first organic ligands may be used as they are, or may be substituted with desired first organic ligands depending on a type of solvent or the like. In any case, the EML obtained by applying and then drying a QD dispersion containing first organic ligands that are known and commonly used as organic ligands contains these first organic ligands.

In the present embodiment, in order to mineralize the EML 13, the ligand substitution step is performed to substitute the first organic ligands coordinated to the QDs 21 with second organic ligands that are thermally decomposed by heating and with the halide ions 31a. As the second ligand, an organic ligand that serves as a precursor of the MX 22 is used.

A method of substituting the first organic ligands coordinated to the QD 21 with the second organic ligands and the halide ions 31a will be described below with reference to FIG. 23.

As illustrated in FIG. 23, in the ligand substitution step, first, a ligand solution 30 in which the halide ions 31a and organic ligands 32 as the second organic ligands are dissolved, and a QD dispersion 40 in which the QDs 21 to which organic ligands 41 are coordinated as the first organic ligands are dispersed are injected into a container 61 (step S21a).

The halide ions 31a are supplied, for example, as metal halides 31. The metal halides 31 exist as the halide ions 31a, which are anions, and metal ions 31b, which are cations. Of these halide ions 31a and metal ions 31b, the halide ions 31a are negatively charged and thus are attracted to the positively charged surface of the QD 21 as halogen ligands.

As described above, examples of the halide ions 31a, which are anions, include a fluoride ion (F⁻), a chloride ion (Cl⁻), a bromide ion (Br⁻), and an iodide ion (I⁻).

Examples of the metal ions 31b, which are cations, include Li⁺, Na⁺, K⁺, Rb⁺, Cs⁺, Be²⁺, Mg²⁺, Ca²⁺, Sr²⁺, Ba²⁺, Zn²⁺, Al³⁺, Ga³⁺, In³⁺, Sn²⁺, and Pb²⁺.

The organic ligand 32 is not limited to any specific ligand as long as it is a compound that is thermally decomposed by heating, contains at least one element among the elements contained in the inorganic compound 23, and serves as a precursor of the MX 22. As the organic ligand 32, for example, xanthic acid is suitably used. Other materials that can be employed as the organic ligand 32 include thiourea, thioacetamide, dithiocarboxylic acid, dithiocarbamic acid, trithiocarbonic acid, dimethylthiourea, and tertiary thiols.

In the following, as an example, a case will be described in which the inorganic compound 23 is ZnS, and the organic ligands 41 are substituted with chloride ions (Cl⁻) as the halide ions 31a and xanthic acids as the organic ligands 32. The xanthic acid is one of the precursors of the MX 22 (ZnS precursor) and is used as one of sulfur (S) sources for ZnS.

FIG. 23 illustrates, as an example, a case in which the metal halide 31 is ZnCl₂, the halide ion 31a is Cl⁻, the metal ion 31b is Zn²⁺, and the organic ligand 32 is the xanthic acid (indicated by “Xan” in FIG. 23).

The ligand solution 30 contains a solvent 33 in which the halide ions 31a and the organic ligands 32 are soluble, and the QD dispersion 40 contains a solvent 42 in which the organic ligands 41 are soluble. For example, the solvent 42 has a different polarity from the solvent 33 and has a lower specific gravity than the solvent 33. Note that to more clearly distinguish a boundary between the ligand solution 30 and the QD dispersion 40, a separation liquid (not illustrated) having a specific gravity and polarity between those of the solvent 33 and the solvent 42 may be injected into the container 61.

The solvent 33 may include at least one type of organic solvent selected from the group consisting of, for example, dimethyl sulfoxide (DMSO), N,N-dimethylformamide (DMF), N-methylformamide (NMF), tetrahydrofuran (THF), formamide, N,N′-dimethylpropyleneurea, dimethylacetamide, N-methylpyrrolidone, gamma-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, and diethyl sulfide. In this case, the solvent 33 well disperses both the QDs 21, to which the halide ions 31a are coordinated, and the precursors of the MX 22. The solvent 33 may be a polar solvent having a higher polarity than the solvent 42. The solvent 33 may be prepared, for example, by dispersing zinc chloride, sodium chloride, hydrochloric acid, or the like in NMF, DMF, DMSO, or the like. The solvent 42 is desirably, for example, toluene, hexane, octane, octadecene, or the like. The solvent 42 is desirably a non-polar solvent that is immiscible with the solvent 33.

As described above, the organic ligand 41 may be a carbon chain commonly used as a ligand for the QD. The solvent 42 is a solvent in which the organic ligands 41 are soluble, so the QDs 21 to which the organic ligands 41 are coordinated are easily dispersed in the QD dispersion 40.

In the ligand solution 30, an excess amount of the halide ions 31a over an amount of the halide ions 31a capable of coordinating to the QDs 21 and an excess amount of the organic ligands 32 over an amount of the organic ligands 32 capable of coordinating to the QDs 21 are dissolved. For example, at least 0.1 mol/l of the halide ions 31a and at least 0.1 mol/l of the organic ligands 32 may be dissolved in the ligand solution 30. In the ligand solution 30, a molar ratio of the dissolved amounts of the halide ions 31a and the organic ligands 32 may be 3:1.

Subsequently, the container 61 containing the ligand solution 30 and the QD dispersion 40 described above is vibrated at high speed by a stirrer to stir the ligand solution 30 and the QD dispersion 40 (step S21b). To improve stirring efficiency, a stir bar may be put into the container 61. In other words, the step of stirring the ligand solution 30 and the QD dispersion 40 is a step of processing the QDs 21 with the halide ions 31a and the organic ligands 32, and in particular, a step of producing the QDs 21 to which the halide ions 31a and the organic ligands 32 are coordinated.

Here, as described above, the ligand solution 30 contains the excess amount of the halide ions 31a and the excess amount of the organic ligands 32. In general, when two or more types of ligands are contained in a solution in which QDs are dispersed, the ligands to be coordinated to the QDs are in equilibrium with the ligands in the solution. Thus, when the ligand solution 30 and the QD dispersion 40 are stirred, at least some of the organic ligands 41 coordinated to the QDs 21 are substituted with the halide ions 31a and the organic ligands 32.

Accordingly, by the stirring, as illustrated in step S21b in FIG. 23, a QD dispersion 51 in which the QDs 21 to which the halide ions 31a and the organic ligands 32 are coordinated are dispersed in the solvent 33, and a ligand solution 52 in which the organic ligands 41 are dissolved in the solvent 42 are obtained in the container 61.

As described above, the QDs 21 to which the halide ions 31a and the organic ligands 32 are coordinated are obtained in the QD dispersion 51. Note that the stirring may be completed when the liquid in the container 61 is irradiated with ultraviolet light or the like and it is confirmed that a liquid layer that emits light has moved from an upper side to a lower side of the container 61.

Subsequently, as illustrated in step S21c in FIG. 23, only the QD dispersion 51 is extracted from the container 61 to a container 62.

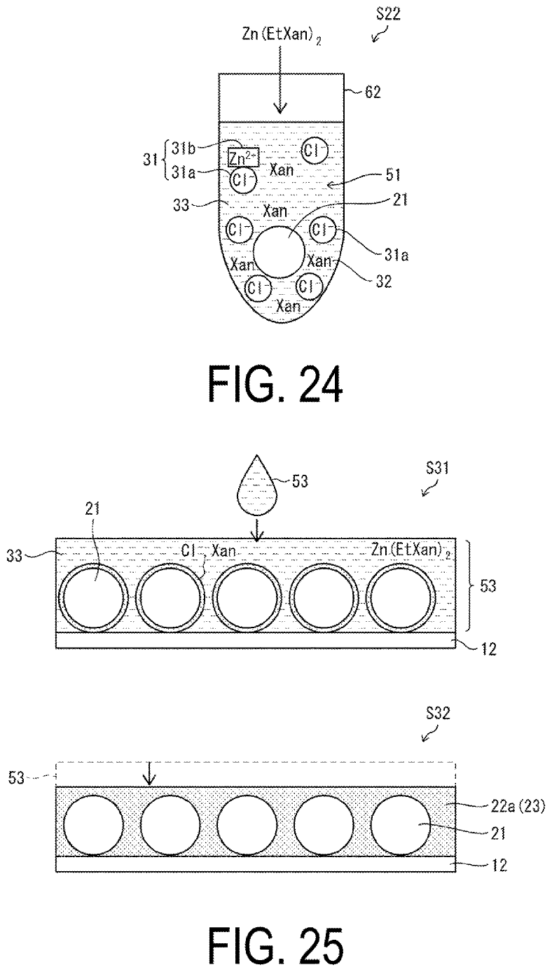

FIG. 24 is a schematic cross-sectional view illustrating a step subsequent to step S21 in step S11.

As illustrated in FIG. 24, when the inorganic compound 23 is ZnS, after step S21c, the QD dispersion 51 extracted in step S21c is mixed with zinc xanthate as the precursor 34 of the MX 22 (ZnS precursor) in the container 62 (step S22). In FIG. 24, Zn(EtXan)₂ represents the zinc xanthate. The zinc xanthate is used as one of the sulfur (S) sources and as a zinc (Zn) source for ZnS.

Thus, the QDs 21 to which the chloride ions (Cl⁻) as the halide ions 31a and the xanthic acids as the organic ligands 32 used as the precursor are coordinated, and the zinc xanthate as the precursor 34 that serves as one of the S sources and the Zn source, are dispersed in, for example, the solvent 33 as a first solvent for dispersing or dissolving. Thus, a QD dispersion 53 (see S31 in FIG. 25) containing QDs 21, the xanthic acids and zinc xanthate as the precursors (ZnS precursors) of the inorganic compound 23 (MX 22), the halide ions 31a, and the solvent 33 is manufactured (prepared).

When the halide ions 31a are used as ligands, a quantum yield (QY) of the resulting light-emitting element 1 is slightly lower than when organic ligands are used.

However, the use of the halide ions 31a as ligands as described above allows QDs 21 to be dispersed in a polar solvent. As illustrated in FIG. 2, for example, when the halide ions 31a are coordinated to the shell 21S of the QD 21, dispersibility of the QDs 21 in the polar solvent is high, and precipitation of the QDs 21 hardly occurs. In addition, when the halide ions 31a are coordinated to the shell 21S of the QD 21, aggregation of the QDs 21 caused by the reaction of the precursors of the MX 22 on the surfaces of the QDs 21 is suppressed, and the dispersibility of the QDs 21 can be maintained for a long period of time.

On the other hand, when the xanthic acids, which are organic ligands, are used, the dispersibility of the QDs 21 in a polar solvent is lower than when halogen ligands are used. However, the use of the xanthic acids as ligands can improve a QY of the resulting light-emitting element 1.

Next, step S3 will be described.

### Step S3

FIG. 25 illustrates examples of step cross-sectional views of some steps in the EML forming step (step S3). Note that in FIG. 25, illustration of the substrate as a support body and the anode electrode 11 is omitted.

As illustrated in FIG. 25, in step S3, first, the QD dispersion 53 manufactured in step S11 is applied onto the HTL 12. As described above, the QD dispersion 53 contains the multiple QDs 21, the xanthic acids and the zinc xanthate as the precursors of the inorganic compound 23 (first inorganic compound), the halide ions 31a, and the solvent 33 as the first solvent. Note that in FIG. 25, Xan represents the xanthic acid, Zn(EtXan)₂ represents the zinc xanthate, and Cl-represents the halide ion 31a. Thus, a coating film consisting of the QD dispersion 53 is formed on the HTL 12 (step S31: quantum dot dispersion applying step).

As a method of forming the coating film, any method such as, for example, a bar coating method, a spin coating method, or an ink-jet method can be appropriately selected.

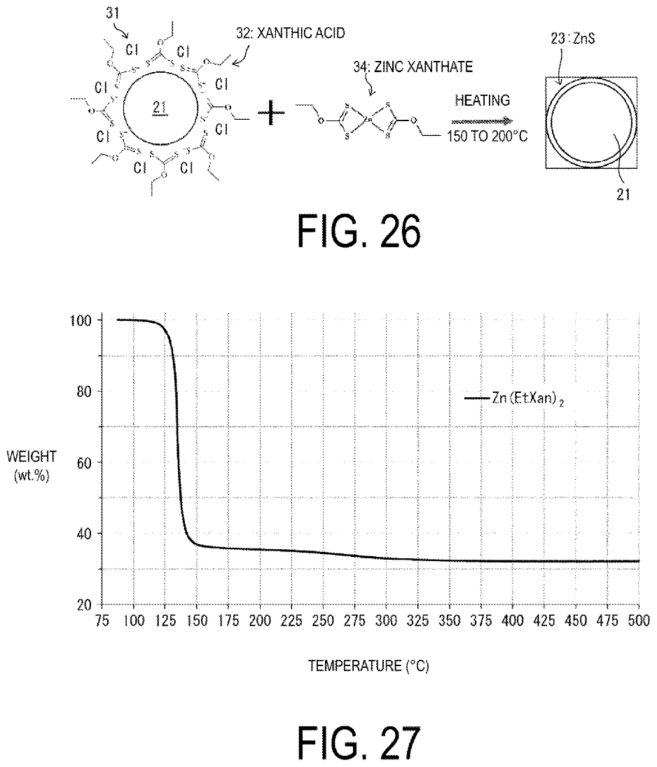

Subsequently, the coating film consisting of the QD dispersion 53 is heated at a temperature equal to or higher than a thermal decomposition temperature of the xanthic acid and the zinc xanthate as the precursors of the inorganic compound 23 (e.g., 150 to 200° C. as shown in FIG. 26). Thus, at least part of the precursors of the inorganic compound 23 is thermally decomposed, and the solvent 33 is removed. Thus, the first film including the multiple QDs 21 and the MX 22 including the inorganic compound 23 that constitutes the first layer 22a is deposited (step S32: first film deposition step).

FIG. 26 is a diagram schematically showing a reaction scheme for manufacturing the inorganic compound 23.

As shown in FIG. 26, the zinc xanthate has a structure in which Zn is bonded to the xanthic acids. The xanthic acids and the zinc xanthate are the precursors of the inorganic compound 23. When these xanthic acids and zinc xanthate are thermally decomposed by heating to vaporize organic components, while Zn and S are bonded to form ZnS. Thus, the QD dispersion 53 forms the bulk inorganic compound 23 by thermal decomposition of the precursors of the inorganic compound 23. Note that when nanoparticles made of an inorganic compound are used as the inorganic compound, many gaps exist between the nanoparticles, making it difficult to achieve the object described above.

FIG. 27 is a graph showing thermal decomposability of the zinc xanthate (Zn(EtXan)₂) and results of measurement by thermal gravimetric analysis (TGA).

As shown in FIG. 27, assuming that a mass of zinc xanthate before heating is 100 wt. %, zinc xanthate is thermally decomposed by heating and the organic components are vaporized, whereby the mass of zinc xanthate gradually decreases. As shown in FIG. 27, zinc xanthate is largely thermally decomposed, for example, between 125° C. and 150° C., and the mass thereof decreases to 40 wt. % or less of the mass thereof before heating.

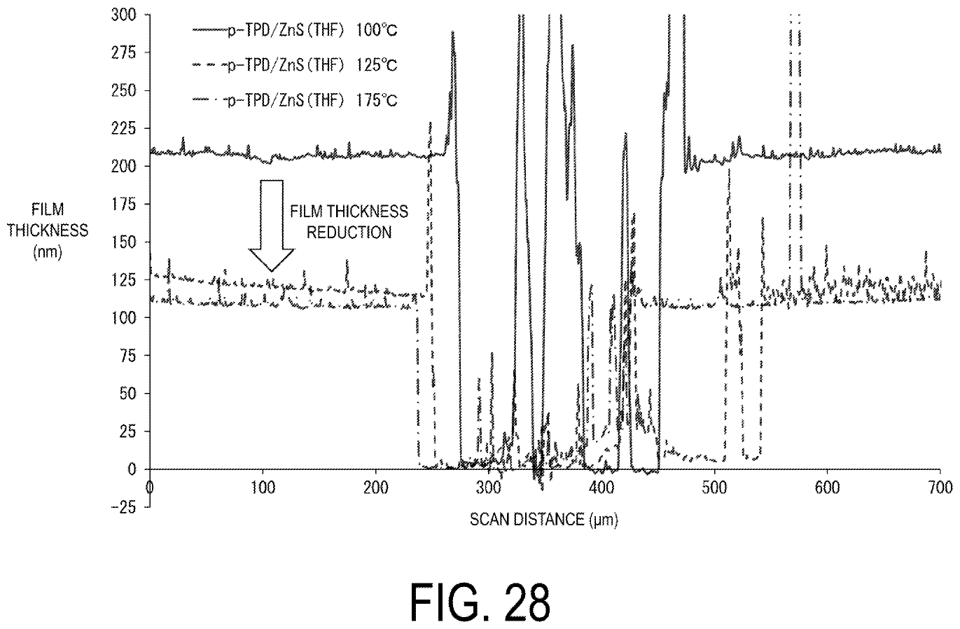

FIG. 28 is a graph showing results of measurement using a film thickness step profiler during deposition of the first film. In FIG. 28, a horizontal axis represents a scan distance and a vertical axis represents a film thickness (step). FIG. 28 shows changes in the film thickness of the first layer 22a of the MX 22 when the coating films consisting of the QD dispersion 53 are heated at 100° C., 125° C., and 175° C., respectively, when p-TPD is used as the HTL 12, THF is used as the solvent 33, and ZnS is used as the inorganic compound 23.

As shown in FIG. 27, when the heating temperature exceeds 125° C., zinc xanthate is thermally decomposed and the mass thereof is greatly reduced, and therefore a volume thereof is reduced, resulting in a decrease in the film thickness of the first layer 22a of the MX 22, as shown in FIG. 28. In particular, when the coating film consisting of the QD dispersion 53 is heated at 175° C., which completely exceeds the thermal decomposition point of zinc xanthate, the entire coating film decomposes, resulting in a great reduction in the mass and the film thickness thereof.

In the present embodiment, a volume of ZnS (in other words, the layer thickness of the first layer 22a) can be adjusted utilizing this mass reduction of the precursors.

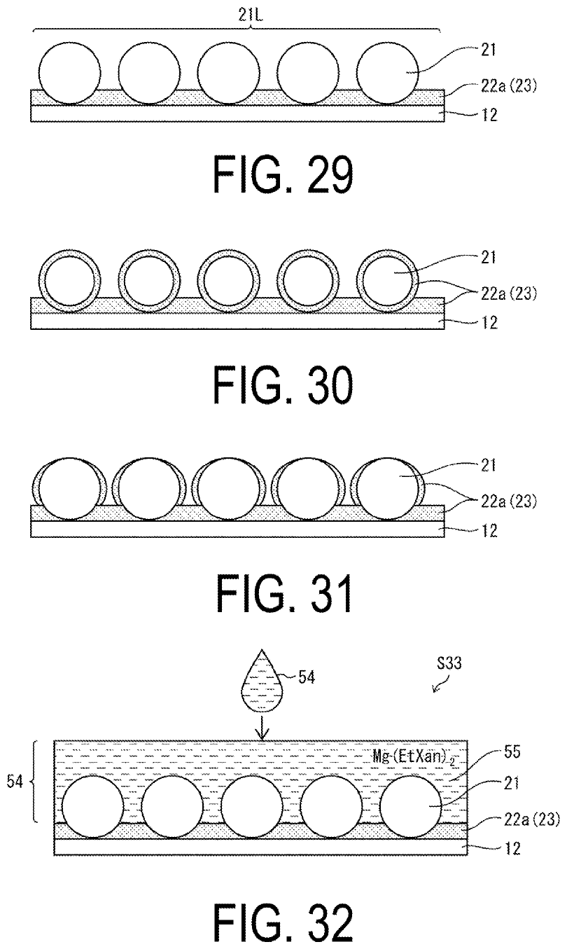

FIGS. 29 to 31 are cross-sectional views illustrating examples of formation of the first layer 22a formed in step S32, respectively.

In step S32, by adjusting the concentrations (medium amounts) of the precursors of the inorganic compound 23 contained in the QD dispersion 53, the mass reductions (film thickness reductions) of the precursors of the inorganic compound 23 can be controlled.

Therefore, by adjusting the concentrations of the precursors of the inorganic compound 23 contained in the QD dispersion 53 so that one outer edge part of the MX 22 containing the inorganic compound 23, which is the interface 221 between the first layer 22a and the second layer 22b illustrated in FIG. 1, intersects with the QD row 21L, for example, the first layer 22a illustrated in FIG. 29 can be formed.

According to the present embodiment, as illustrated in FIG. 29, it is possible to change the concentration of, for example, the inorganic compound 23 contained in the MX 22 within the range of the thickness of one QD 21 in the layer thickness direction of the EML 13. Thus, even when only one layer of the QDs 21 is stacked in the layer thickness direction of the EML 13, the carrier balance can be adjusted, thereby improving luminous efficiency.

In step S32, for example, when adhesion of the inorganic compound 23 to the QDs 21 is good, the inorganic compound 23 is formed around the QDs 21, and then the overall volume of the first layer 22a is reduced. In this case, by adjusting the concentrations of the precursors of the inorganic compound 23 to control the mass reductions (film thickness reductions) of the precursors of the inorganic compound 23, for example, the first layer 22a illustrated in FIG. 30 or 31 can be formed.

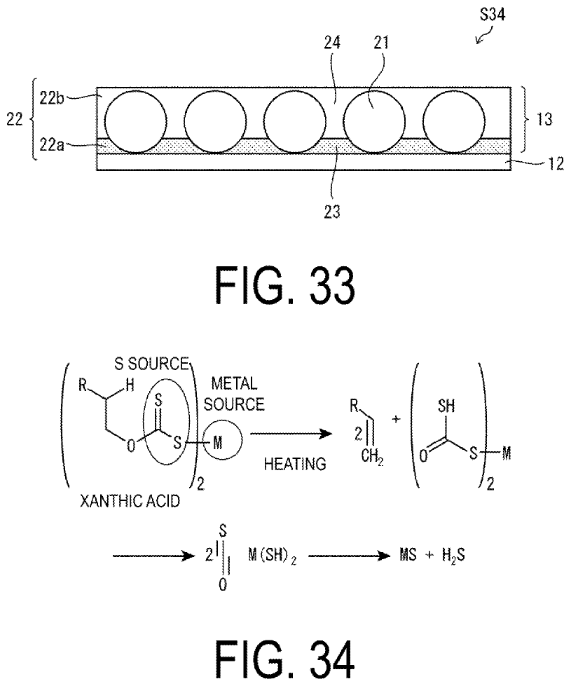

FIGS. 32 and 33 are step cross-sectional views illustrating examples of some steps in the EML forming step (step S3), respectively. Note that FIGS. 32 and 33 illustrate, as an example, a case in which the second layer 22b is formed on the first layer 22a illustrated in FIG. 29.

Thus, when the QD dispersion 53 containing QDs 21 and the xanthic acids and the zinc xanthate as the precursors of the inorganic compound 23 is applied onto, for example, the HTL 12 that serves as an underlayer, and heated, the xanthic acids and the zinc xanthate around the QDs 21 decompose. Thus, ZnS as the inorganic compound 23 is formed, so that the QDs 21 are covered with ZnS and part of the MX 22 is formed. At this time, as described above, by adjusting the concentrations of the precursors of the inorganic compound 23, only areas surrounding the QDs 21 can be covered with the inorganic compound 23, or areas surrounding the areas surrounding the QDs 21 can be further covered with the inorganic compound 23.

As illustrated in FIGS. 22 and 32, in step S3, after step S32, an inorganic compound precursor solution 54 is supplied onto the first film formed in step S32 as a second inorganic compound precursor solution containing a precursor of the inorganic compound 24 (step S33: second inorganic compound precursor solution supplying step).

The inorganic compound precursor solution 54 contains the precursor of the inorganic compound 24 and a solvent 55 (second solvent) that dissolves the inorganic compound 24. As the solvent 55, a similar solvent to the solvent exemplified as the first solvent can be used. Note that FIG. 32 illustrates an example in which the inorganic compound 24 is magnesium sulfide (MgS) and magnesium xanthate is used as the precursor of the inorganic compound 24. Note that in FIG. 32, Mg(EtXan)₂ represents the magnesium xanthate. Thus, a coating film consisting of the inorganic compound precursor solution 54 is formed on the first film.

Note that the supply of the inorganic compound precursor solution 54 onto the first film is not limited to any specific method. The inorganic compound precursor solution 54 may be, for example, sprayed onto the first film, or the inorganic compound precursor solution 54 may be applied onto the first film by a bar coating method, a spin coating method, an ink-jet method, or the like.

Subsequently, the inorganic compound precursor solution 54 supplied in step S33 is heated at a temperature equal to or higher than a thermal decomposition temperature of the precursor of the inorganic compound 24 to thermally decompose at least part of the precursor of the inorganic compound 24 and remove the solvent 55. The magnesium xanthate used as the precursor of the inorganic compound 24, as well as the zinc xanthate, gradually loses a mass thereof by thermal decomposition and vaporization of the organic components when heated, which reduces a volume thereof, thereby reducing the film thickness of the second layer 22b of the MX 22. Thus, as illustrated in FIG. 33, the MX 22 containing the inorganic compound 24 as a main component as the second layer 22b is formed (step S34: second inorganic compound forming step). Thus, the EML 13 is formed, which includes the QDs 21 and also includes the first layer 22a and the second layer 22b as the MX 22.

FIG. 34 is a diagram showing a reaction scheme for forming a metal sulfide from a precursor of the metal sulfide when the MX 22 contains the metal sulfide as an inorganic compound as described above. Note that in FIG. 34, M represents a metal source, and R represents any organic residue. As described above, when the inorganic compound 24 is MgS and magnesium xanthate is used as the precursor of the inorganic compound 24, M is magnesium (Mg). The magnesium xanthate is used as an S source and an Mg source for MgS.

The magnesium xanthate is the precursor of the inorganic compound 24. When the magnesium xanthate is thermally decomposed by heating to vaporize organic components, while Mg and S are bonded to form MgS. Thus, the inorganic compound precursor solution 54 forms the bulk inorganic compound 24 by thermal decomposition of the precursor of the inorganic compound 24.

Thus, in the present embodiment, the inorganic compound precursor solution 54 containing the precursor of the inorganic compound 24 is supplied onto the first film containing the multiple QDs 21 and the inorganic compound 23, and heated, so that the second layer 22b of the MX 22 is formed on the first film as the MX 22 containing the inorganic compound 24 as a main component.

Note that, as illustrated in FIG. 26, when the inorganic compound is ZnS and ZnS is used as a precursor of the inorganic compound, M illustrated in FIG. 34 is Zn. When the inorganic compound is InS (e.g., In₂S₃) and indium xanthate is used as a precursor of the inorganic compound, M is indium (In). The indium xanthate is used as an S source and an In source for InS.

### MODIFIED EXAMPLE

FIG. 1 illustrates an example in which the anode electrode 11 is a lower layer electrode, the cathode electrode 15 is an upper layer electrode, and the EML 13 is located on the HTL 12. However, the disclosure is not limited thereto.

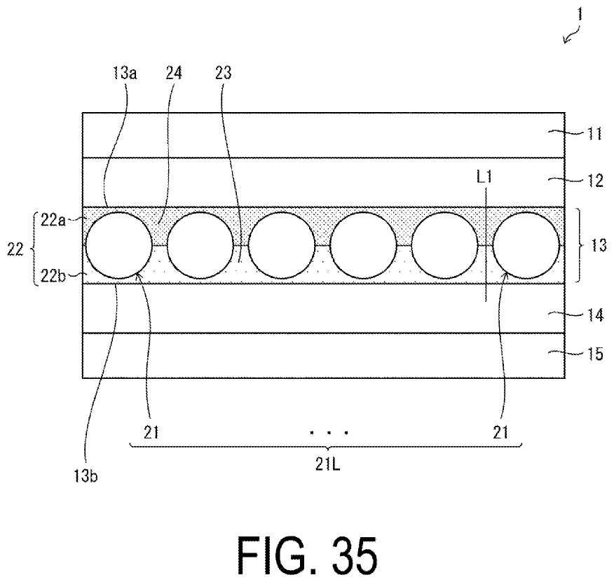

FIG. 35 is a cross-sectional view illustrating an example of a schematic configuration of a light-emitting element 1 according to the present modified example.

The light-emitting element 1 may have a conventional structure as illustrated in FIG. 1, or may have an inverted structure as illustrated in FIG. 35.

The light-emitting element 1 illustrated in FIG. 35 has a configuration in which the cathode electrode 15 is the lower layer electrode, the anode electrode 11 is the upper layer electrode, and the HTL 12 is located on the EML 13. As illustrated in FIG. 35, the light-emitting element 1 may have a configuration in which, for example, the cathode electrode 15, the ETL 14, the EML 13, the HTL 12, and the anode electrode 11 are located in this order from the lower layer side (e.g., a support body side (not illustrated) such as the substrate).

In this case, as illustrated in FIG. 35, the layering order in the light-emitting element 1 is reversed from that in the light-emitting element 1 illustrated in FIG. 1. Thus, when manufacturing such a light-emitting element 1, first, the cathode electrode 15 is formed on the substrate as the support body (step S5: cathode electrode forming step). Subsequently, the ETL 14 is formed (step S4: ETL forming step). In parallel, the QD dispersion is manufactured (prepared) (step S11: QD dispersion manufacturing step). Subsequently, the EML 13 is formed using the QD dispersion (step S3: EML forming step). Subsequently, the HTL 12 is formed (step S2: HTL forming step). Subsequently, the anode electrode 11 is formed (step S1: anode electrode forming step). In this way, the light-emitting element 1 is manufactured.

In this case, the inorganic compound 24 is used as the first inorganic compound, and the inorganic compound 23 is used as the second inorganic compound. Therefore, in step S11, a QD dispersion containing precursors of the inorganic compound 24 instead of the precursors of the inorganic compound 23 is manufactured. Thus, as a first solvent contained in the QD dispersion, for example, when the inorganic compound 24 is MgS, the QD dispersion is manufactured that contains, for example, QDs 21, the xanthic acids and the magnesium xanthate as the precursors (MgS precursors) of the inorganic compound 24 (MX 22), the halide ions 31a, and a solvent (first solvent) that disperses or dissolves them.

In step S33, an inorganic compound precursor solution containing a precursor of the inorganic compound 23 is supplied as a second inorganic compound precursor solution onto the first film formed using the QD dispersion in step S32.

### Second Embodiment

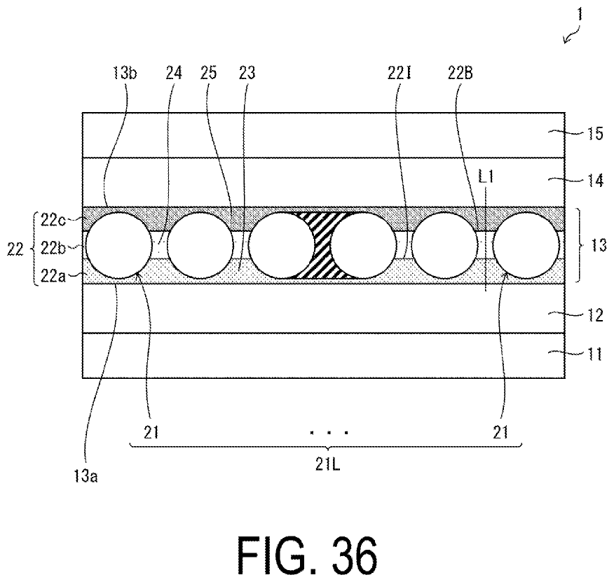

FIG. 36 is a cross-sectional view illustrating an example of a schematic configuration of a light-emitting element 1 according to the present embodiment.

An MX 22 may contain an inorganic compound other than an inorganic compound 23 and an inorganic compound 24.

The MX 22 illustrated in FIG. 36 further contains, as an inorganic compound, an inorganic compound 25 in addition to the inorganic compound 23 and the inorganic compound 24.

Therefore, in the light-emitting element 1 illustrated in FIG. 36, the MX 22 has a first region containing at least the inorganic compound 23, a second region containing at least the inorganic compound 24, and a third region containing at least the inorganic compound 25, in a direction of a straight line L1 passing through an outer edge part 13a and an outer edge part 13b in an EML 13. The second region is located closer to the outer edge part 13b than the first region. The third region is located closer to the outer edge part 13b than the second region.

In this case, the first region contains the inorganic compound 23 as a main component. The first region may further contain the inorganic compound 24, or may contain the inorganic compound 23 and the inorganic compound 25. The second region contains the inorganic compound 24 as a main component. The second region may further contain the inorganic compound 23 or the inorganic compound 25, or may further contain the inorganic compound 23 and the inorganic compound 25. The third region contains the inorganic compound 25 as a main component. The third region may further contain the inorganic compound 24, or may further contain the inorganic compound 24 and the inorganic compound 23.

In this case, a concentration of the inorganic compound 23 in the first region is different from concentrations of the inorganic compound 23 in the second region and the third region by at least a certain amount. In this case, it is desirable that the concentration of the inorganic compound 23 in the first region be different from the concentrations of the inorganic compound 23 in the second region and the third region by at least 20%.

A concentration of the inorganic compound 24 in the second region is different from concentrations of the inorganic compound 24 in the first region and the third region by at least a certain amount. In this case, it is desirable that the concentration of the inorganic compound 24 in the second region be different from the concentrations of the inorganic compound 24 in the first region and the third region by at least 20%.

A concentration of the inorganic compound 25 in the third region is different from concentrations of the inorganic compound 25 in the first region and the second region by at least a certain amount. In this case, it is desirable that the concentration of the inorganic compound 25 in the third region be different from the concentrations of the inorganic compound 25 in the first region and the second region by at least 20%.

Note that in the first region, by sandwiching the second region between the first region and the third region, a degree of penetration of the inorganic compound 24 into the first region is different from a degree of penetration of the inorganic compound 25 into the first region. Thus, in the first region, the concentration of the inorganic compound 24 is different from the concentration of the inorganic compound 25, and the concentration of the inorganic compound 24 is greater than the concentration of the inorganic compound 25. Similarly, in the third region, by sandwiching the second region between the third region and the first region, a degree of penetration of the inorganic compound 24 into the third region is different from a degree of penetration of the inorganic compound 23 into the third region. Thus, in the third region, the concentration of the inorganic compound 24 is different from the concentration of the inorganic compound 23, and the concentration of the inorganic compound 24 is greater than the concentration of the inorganic compound 23. However, in the second region, the inorganic compound 23 and the inorganic compound 25 may have the same concentration.

Note that the concentrations of the inorganic compound 23, the inorganic compound 24, and the inorganic compound 25 can be measured by a method similar to any of the methods described with reference to FIGS. 8, 10, 12, and 13 in the first embodiment.

FIG. 36 illustrates an example in which the MX 22 has, as the first region, a first layer 22a mainly composed of the inorganic compound 23, as the second region, a second layer 22b mainly composed of the inorganic compound 24, and as the third region, a third layer 22c mainly composed of the inorganic compound 25. FIG. 36 illustrates an example in which the EML 13 has one QD row 21L in a layer thickness direction of the EML 13, in which multiple QDs 21 are arranged in a direction perpendicular to the layer thickness direction of the EML 13, and an interface 221 between the first layer 22a and the second layer 22b and an interface 22B between the second layer 22b and the third layer 22c each intersect with the QD row 21L. However, the present embodiment is not limited to this. In the present embodiment as well, for example, as illustrated in FIGS. 15 to 21, the QDs 21 may be stacked in multiple layers in the layer thickness direction of the EML 13, and the interface between the layers may not be clearly separated.

Also in the present embodiment, it is desirable that the EML 13 has, within a range of at least 1 nm from the outer edge part 13a, a region in which the concentration of the inorganic compound 23 in the MX 22 is 80% or more. As described above, when the MX 22 near the outer edge part 13a is formed of a relatively uniform component in this manner, carriers can be easily injected from an anode electrode 11 side into the QDs 21 near the outer edge part 13a.

In the present embodiment, it is desirable that the EML 13 has, within a range of at least 1 nm from the outer edge part 13b, a region in which the concentration of the inorganic compound 25 in the MX 22 is 80% or more. When the MX 22 near the outer edge part 13b is formed of a relatively uniform component in this manner, carriers can be easily injected from the cathode electrode 15 side into the QDs 21 near the outer edge part 13b.

Also in the present embodiment, for example, in a case of electron excess and hole deficiency, it is desirable to reduce an amount of electrons to be injected or increase an amount of holes to be injected in the EML 13 in order to improve the carrier balance.

Therefore, in the case of electron excess and hole deficiency as described above, for example, it is desirable to use an inorganic compound having a larger Eg than the inorganic compound 23 as the inorganic compound 24, and to use an inorganic compound having a larger Eg than the inorganic compound 24 as the inorganic compound 25. In other words, it is desirable to use an inorganic compound having a smaller Eg than the inorganic compound 24 as the inorganic compound 23, and to use an inorganic compound having a smaller Eg than the inorganic compound 25 as the inorganic compound 24. In this case, the injection of electrons is suppressed to adjust the carrier balance, thereby improving luminous efficiency and reliability.

In the case of electron excess and hole deficiency as described above, for example, it is desirable to use an inorganic compound having a higher hole mobility than the inorganic compound 24 as the inorganic compound 23, and to use an inorganic compound having a lower electron mobility than the inorganic compound 24 as the inorganic compound 25. In this case, the injection of holes is facilitated while the injection of electrons is suppressed to adjust the carrier balance, thereby improving luminous efficiency and reliability.

Therefore, in the case of electron excess and hole deficiency as described above, for example, the inorganic compound 23 may be indium sulfide (InS), the inorganic compound 24 may be zinc sulfide (ZnS), and the inorganic compound 25 may be magnesium sulfide (MgS). Also in this case, examples of the indium sulfide (InS) include In₂S₃.

Thus, in the case of electron excess and hole deficiency, for example, by changing the MX 22 on the HTL 12 side (to be specific, the inorganic compound 23) to the MX 22 mainly composed of an inorganic compound having a smaller Eg and a higher hole mobility (smaller hole effective mass) than the MX 22 on an ETL 14 side (to be specific, the inorganic compound 25), the hole injection can be promoted and the electron excess can be adjusted. In addition, for example, by changing the MX 22 on the ETL 14 side to the MX 22 mainly composed of an inorganic compound having a larger Eg and a lower electron mobility (larger electron effective mass) than the MX 22 on the HTL 12 side, the electron injection can be suppressed and the hole deficiency can be adjusted.

On the other hand, in a case of electron deficiency and hole excess, for example, it is desirable to use an inorganic compound having a larger Eg than the inorganic compound 24 as the inorganic compound 23 and an inorganic compound having a larger Eg than the inorganic compound 24 as the inorganic compound 25. In other words, it is desirable to use an inorganic compound having a smaller Eg than the inorganic compound 23 as the inorganic compound 24 and to use an inorganic compound having a smaller Eg than the inorganic compound 24 as the inorganic compound 25. In this case, the injection of holes is suppressed to adjust the carrier balance, thereby improving luminous efficiency and reliability.

In the case of electron deficiency and hole excess as described above, for example, it is desirable to use an inorganic compound having a higher electron mobility than the inorganic compound 23 as the inorganic compound 24, and to use an inorganic compound having a higher electron mobility than the inorganic compound 24 as the inorganic compound 25. In this case, the injection of electrons is facilitated to adjust the carrier balance, thereby improving luminous efficiency and reliability.

### Method for Manufacturing Light-Emitting Element 1

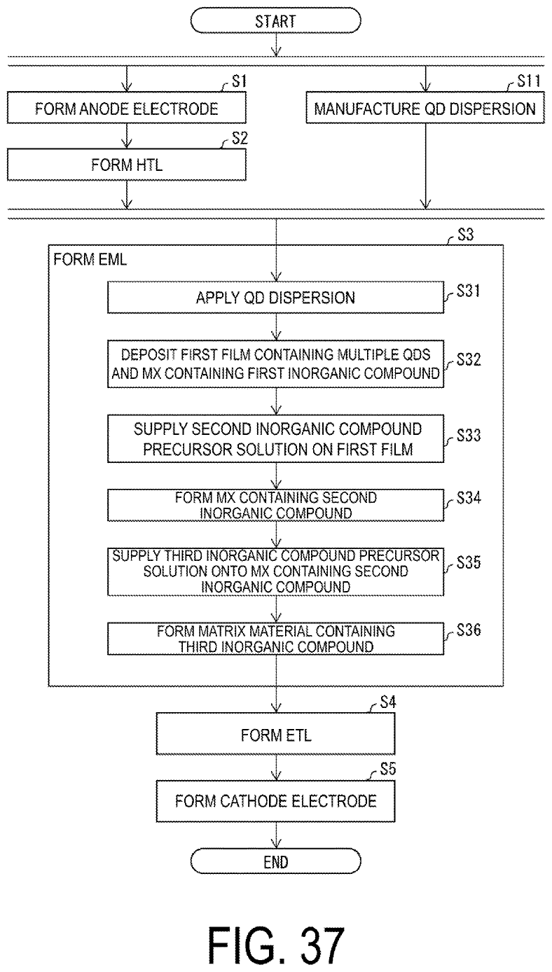

FIG. 37 is a flowchart illustrating an example of a method for manufacturing the light-emitting element 1 according to the present embodiment.

The method for manufacturing the light-emitting element 1 according to the present embodiment is the same as the method for manufacturing the light-emitting element 1 according to the first embodiment, except for the following points.

In the method for manufacturing the light-emitting element 1 according to the present embodiment, as illustrated in FIG. 37, in step S3, a third inorganic compound precursor solution containing a precursor of the inorganic compound 25 is supplied onto the MX 22 containing the inorganic compound 24 as a main component, which is formed as the second layer 22b in step S34 (step S35: third inorganic compound precursor solution supplying step).

The third inorganic compound precursor solution contains the precursor of the inorganic compound 25 and a solvent (third solvent) that dissolves the inorganic compound 25. As the third solvent, a similar solvent to the solvent exemplified as the first solvent can be used. Step S35 (third inorganic compound precursor solution supplying step) can be performed in a manner similar to step S33 (second inorganic compound precursor solution supplying step).

As described above, for example, indium sulfide (e.g., In₂S₃) can be used as the inorganic compound 23. As the inorganic compound 24, for example, zinc sulfide (ZnS) can be used. As the inorganic compound 25, for example, magnesium sulfide (MgS) can be used. In this case, xanthic acid and indium xanthate are used as the precursors of the inorganic compound 23. Zinc xanthate is used as the precursor of the inorganic compound 24. Magnesium xanthate is used as the precursor of the inorganic compound 25. A reaction scheme is as shown in FIG. 34.

Subsequently, the third inorganic compound precursor solution supplied in step S35 is heated at a temperature equal to or higher than a thermal decomposition temperature of the precursor of the inorganic compound 25 to thermally decompose at least part of the precursor of the inorganic compound 25 and remove the third solvent. Thus, the MX 22 containing the inorganic compound 25 as a main component as the third layer 22c is formed (step S36: third inorganic compound forming step). Thus, the EML 13 is formed that includes the QDs 21 and the first layer 22a, the second layer 22b, and the third layer 22c as the MX 22.

Thus, according to the present embodiment, it is possible to manufacture the light-emitting element 1 that can improve luminous efficiency by more finely adjusting the carrier balance.

Note that in the present embodiment, the case in which the MX 22 contains three types of inorganic compounds is described as an example, but the present embodiment is not limited thereto. The MX 22 may contain, for example, four or more types of inorganic compounds.

### Third Embodiment

A light-emitting element 1 can be suitably used as a light source for a light-emitting device such as a display device or a lighting system. It is sufficient that the light-emitting device includes at least one light-emitting element 1. In the following, a case in which the light-emitting element 1 is used as a light source for a display device will be described as an example.

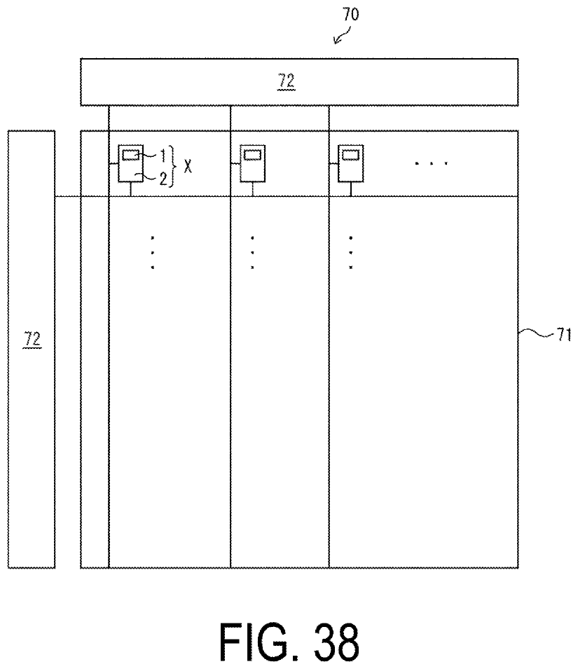

FIG. 38 is a plan view illustrating a configuration example of the display device according to the present embodiment. As illustrated in FIG. 38, a display device 70 includes a display unit 71 including multiple subpixels X, and a driver circuit 72 that drives the display unit 71. For example, the subpixel X includes the light-emitting element 1 described in the first or second embodiment and a pixel circuit 2. The display device 70 may be a lighting system.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
a first electrode;
a second electrode; and
a light-emitting layer located between the first electrode and the second electrode,
wherein the light-emitting layer includes multiple quantum dots and a matrix material,
the matrix material includes a first inorganic compound and a second inorganic compound,
the matrix material includes, in a direction of a straight line passing through a first outer edge part on a first electrode side and a second outer edge part on a second electrode side in the light-emitting layer, a first region including at least the first inorganic compound and a second region including at least the second inorganic compound,
the second region is located closer to the second outer edge part than the first region, and
a concentration of the first inorganic compound in the first region is different from a concentration of the first inorganic compound in the second region by at least a certain amount.

2. The light-emitting element according to claim 1,
wherein the light-emitting layer includes, within a range of at least 1 nm from the first outer edge part, a region in which a concentration of the first inorganic compound in the matrix material is 80% or more.

3. The light-emitting element according to claim 1,
wherein a concentration of at least one of the first inorganic compound and the second inorganic compound changes continuously or stepwise in the direction of the straight line.

4. The light-emitting element according to claim 1,
wherein an interface between the first region and the second region intersects with the multiple quantum dots.

5. The light-emitting element according to claim 1,
wherein the light-emitting layer includes at least one quantum dot row in a layer thickness direction of the light-emitting layer, in which the multiple quantum dots are arranged in a direction perpendicular to the layer thickness direction of the light-emitting layer,
the matrix material includes, as the first region, a first layer mainly composed of the first inorganic compound, and includes, as the second region, a second layer mainly composed of the second inorganic compound, and
an interface between the first layer and the second layer intersects with the at least one quantum dot row.

6. The light-emitting element according to claim 1,
wherein the concentration of the first inorganic compound in the first region is greater than a concentration of the second inorganic compound in the first region, and a concentration of the second inorganic compound in the second region is greater than the concentration of the first inorganic compound in the second region.

7. The light-emitting element according to claim 6,
wherein the first electrode is an anode electrode,
the second electrode is a cathode electrode, and
the second inorganic compound has a larger band gap than the first inorganic compound or the first inorganic compound has a larger band gap than the second inorganic compound.

8. (canceled)

9. The light-emitting element according to claim 6,
wherein the first electrode is an anode electrode,
the second electrode is a cathode electrode, and
the first inorganic compound has a higher hole mobility than the second inorganic compound or the second inorganic compound has a higher electron mobility than the first inorganic compound.

10. (canceled)

11. The light-emitting element according to claim 1,
wherein
the first inorganic compound and the second inorganic compound are metal sulfides,
the first inorganic compound is indium sulfide and the second inorganic compound is magnesium sulfide,
the first inorganic compound is zinc sulfide and the second inorganic compound is magnesium sulfide, or
the first inorganic compound is indium sulfide and the second inorganic compound is zinc sulfide.

12. (canceled)

13. (canceled)

14. (canceled)

15. The light-emitting element according to claim 1,
wherein the light-emitting layer includes, within a range of at least 1 nm from the second outer edge part, a region in which a concentration of the second inorganic compound in the matrix material is 80% or more.

16. The light-emitting element according to claim 1,
wherein the matrix material further includes a third inorganic compound,
the matrix material further includes a third region including at least the third inorganic compound in the direction of the straight line,
the third region is located closer to the second outer edge part than the second region, and
a concentration of the third inorganic compound in the third region is different from a concentration of the third inorganic compound in at least one of the first region and the second region by at least a certain amount.

17. The light-emitting element according to claim 7,
wherein the matrix material further includes a third inorganic compound,
in a case where the second inorganic compound has a larger band gap than the first inorganic compound, the third inorganic compound has a larger band gap than the second inorganic compound,
in a case where the first inorganic compound has a larger band gap than the second inorganic compound, the third inorganic compound has a smaller band gap than the second inorganic compound,
the matrix material further includes a third region including at least the third inorganic compound in the direction of the straight line,
the third region is located closer to the second outer edge part than the second region, and
a concentration of the third inorganic compound in the third region is higher than concentrations of the third inorganic compound in the first region and the second region.

18. (canceled)

19. The light-emitting element according to claim 9,
wherein the matrix material further includes a third inorganic compound,
in a case where the first inorganic compound has a higher hole mobility than the second inorganic compound, the third inorganic compound has a lower electron mobility than the second inorganic compound,
in a case where the second inorganic compound has a higher electron mobility than the first inorganic compound, the third inorganic compound has a higher electron mobility than the second inorganic compound,
the matrix material further includes a third region including at least the third inorganic compound in the direction of the straight line,
the third region is located closer to the second outer edge part than the second region, and
a concentration of the third inorganic compound in the third region is higher than concentrations of the third inorganic compound in the first region and the second region.

20. (canceled)

21. (canceled)

22. The light-emitting element according to claim 16,
wherein the light-emitting layer includes, within a range of at least 1 nm from the second outer edge part, a region in which a concentration of the third inorganic compound in the matrix material is 80% or more.

23. The light-emitting element according to claim 1,
wherein each of the multiple quantum dots includes a core and a shell,
a band gap of at least one type of inorganic compound included in the matrix material is greater than a band gap of the core or the shell, and
an average distance between cores of quantum dots adjacent to each other among the multiple quantum dots is 3 nm or more.

24. (canceled)

25. (canceled)

26. The light-emitting element according to claim 1,
wherein the matrix material includes a continuous film having an area of 1000 nm² or more in a plane direction orthogonal to a thickness direction of the light-emitting layer.

27. The light-emitting element according to claim 1,
wherein the multiple quantum dots are dispersed in the matrix material.

28. (canceled)

29. The light-emitting element according to claim 1,
wherein the matrix material further includes halogen elements.

30. The light-emitting element according to claim 29,
wherein the matrix material includes 1 atom % or more of the halogen elements.

31. The light-emitting element according to claim 29,
wherein a mean value of concentrations of the sum of the halogen elements in a region within 1 nm from the outermost surfaces of the multiple quantum dots in the matrix material is 10% or more higher than a mean value of concentrations of the sum of the halogen elements in a region at a distance exceeding 1 nm from the outermost surfaces of the multiple quantum dots in the matrix material.

32. (canceled)

33. (canceled)

34. (canceled)

35. (canceled)
